(19) United States
(12) Patent Application Publication
(10) Pub. No.: US 2014/0237177 A1
(43) Pub. Date: Aug. 21, 2014

(54) MEMORY MODULE AND MEMORY SYSTEM HAVING THE SAME

(71) Applicant: Samsung Electronics Co., Ltd., Suwon-si (KR)

(72) Inventors: Hak-Soo YU, Seongnam-si (KR); Chul-Woo PARK, Suwon-si (KR); Jung-Bae LEE, Seongnam-si (KR)

(73) Assignee: Samsung Electronics Co., Ltd., Suwon-si (KR)

(21) Appl. No.: 14/171,343

(22) Filed: Feb. 3, 2014

(30) Foreign Application Priority Data
Feb. 18, 2013 (KR) 10-2013-0016839

(51) Int. Cl. G11C 11/406

(52) U.S. Cl. CPC G11C 11/40607
USPC 711/106

(57) ABSTRACT

A memory module includes a master memory device and at least one slave memory device. The master memory device may generate a refresh clock signal, and perform a refresh operation in synchronization with the refresh clock signal. The slave memory device may be connected to receive the refresh clock signal, and perform a refresh operation in synchronization with the refresh clock signal.

### CROSS-REFERENCE TO RELATED APPLICATION(S)

This application claims priority under 35 USC §119 to Korean Patent Application No. 10-2013-0016839, filed on Feb. 18, 2013 in the Korean Intellectual Property Office (KIPO), the contents of which are herein incorporated by reference in their entirety.

### BACKGROUND

1. Technical Field

Example embodiments relate to a semiconductor device, and more particularly to a memory module and a memory system including the memory module.

2. Description of the Related Art

In general, a volatile memory device, such as a dynamic random access memory (DRAM), requires a refresh operation to maintain stored data. Therefore, a memory controller periodically provides refresh commands to a memory device to refresh the memory device in a normal access mode.

However, as a density of a memory device increases, the refresh commands consume more power and decrease the efficiency of a command bus.

### SUMMARY

Some example embodiments provide a memory module that internally performs a refresh operation in a normal access mode.

Some example embodiments provide a memory system including the memory module.

According to example embodiments, a memory module includes a master memory device and a plurality of slave memory devices. The master memory device generates a refresh clock signal, and performs a refresh operation in synchronization with the refresh clock signal. The plurality of slave memory devices receive the refresh clock signal, and perform a refresh operation in synchronization with the refresh clock signal.

In example embodiments, each of the master memory device and the slave memory devices may include a refresh pin and transmit and/or receive the refresh clock signal through the refresh pin.

The master memory device may directly provide the refresh clock signal to each of the plurality of slave memory devices through the refresh pin.

The master memory device may provide the refresh clock signal to a slave memory device adjacent to the master memory device through the refresh pin, and each of the plurality of slave memory devices may receive the refresh clock signal through a first refresh pin and provide the refresh clock signal to an adjacent slave memory device through a second refresh pin.

Each of the master memory device and the slave memory devices may include a first node coupled to the refresh pin, a selection circuit configured to output one of a first voltage and a second voltage, an oscillation circuit being disabled when receiving the first voltage from the selection circuit, generating the refresh clock signal when receiving the second voltage from the selection circuit, and providing the refresh clock signal to the first node, and a buffer configured to store the refresh clock signal received from the first node and output the refresh clock signal. The selection circuit included in the master memory device may output the second voltage and the selection circuit included in each of the plurality of slave memory devices may output the first voltage.

The selection circuit may selectively output one of the first voltage and the second voltage by cutting a fuse in the selection circuit.

The selection circuit may selectively output one of the first voltage and the second voltage according to a programmed configuration value.

In example embodiments, the memory module may further include a plurality of auto-refresh memory devices configured to perform a refresh operation in response to a refresh command received from a memory controller.

Each of the plurality of auto-refresh memory devices may generate an inner refresh clock signal, and perform the refresh operation in synchronization with the inner refresh clock signal when receiving the refresh command from the memory controller.

According to example embodiments, a memory system includes a memory module and a memory controller. The memory module includes a master memory device and a plurality of slave memory devices. The master memory device generates a refresh clock signal, and performs a refresh operation in synchronization with the refresh clock signal. The plurality of slave memory devices receive the refresh clock signal, and perform a refresh operation in synchronization with the refresh clock signal. The memory controller controls the memory module.

In example embodiments, when each of the master memory device and the slave memory devices receives an active command on a row address from the memory controller while performing the refresh operation on the row address, each of the master memory device and the slave memory devices may perform the active command on the row address after finishing the refresh operation on the row address.

When each of the master memory device and the slave memory devices receives a read command from the memory controller after receiving the active command, each of the master memory device and the slave memory devices may perform the read command after a row address-to-column address delay (tRCD) from a time at which the active command is performed and provide a data strobe signal (DQS) and read data to the memory controller after a column address strobe (CAS) latency (tCL) from a time at which the read command is performed.

In a read mode, the memory controller may sample the read data in synchronization with the data strobe signal (DQS) provided from each of the master memory device and the slave memory devices.

When each of the master memory device and the slave memory devices receives a write command from the memory controller after receiving the active command, each of the master memory device and the slave memory devices may perform the write operation after a row address-to-column address delay (tRCD) from the time at which the active command is performed and continuously toggle a data strobe signal (DQS) from the time at which a toggling of the data strobe signal (DQS) provided from the memory controller stops until the performance of the write operation finishes.

In a write mode, the memory controller may deem that a write operation on each of the master memory device and the slave memory devices finishes at the time when the toggling of the data strobe signal (DQS) provided from each of the master memory device and the slave memory devices stops.

### BRIEF DESCRIPTION OF THE DRAWINGS

Illustrative, non-limiting example embodiments will be more clearly understood from the following detailed description in conjunction with the accompanying drawings.

FIG. 1 is a block diagram illustrating an electronic system according to example embodiments.

FIG. 2 is a block diagram illustrating an example of a memory system of FIG. 1 according to example embodiments.

FIG. 3 is a block diagram illustrating another example of a memory system of FIG. 1 according to example embodiments.

FIG. 4 is a block diagram illustrating an example of a memory device included in a memory module of FIG. 2 according to example embodiments.

FIG. 5 is a block diagram illustrating an example of a refresh control circuit included in the memory device of FIG. 4.

FIG. 6 is a block diagram illustrating an example of a refresh clock generator included in the refresh control circuit of FIG. 5.

FIG. 7 is a block diagram illustrating an example of the refresh clock generator of FIG. 6 when the refresh clock generator is included in a master memory device.

FIG. 8 is a block diagram illustrating an example of the refresh clock generator of FIG. 6 when the refresh clock generator is included in a slave memory device.

FIG. 9 is a timing diagram describing an operation of a memory device included in a memory system of FIG. 1 for resolving a conflict between a read operation and a refresh operation.

FIG. 10 is a timing diagram describing an operation of a memory device included in a memory system of FIG. 1 for resolving a conflict between a write operation and a refresh operation.

FIGS. 11 to 14 are block diagrams illustrating some examples of a memory module included in a memory system of FIG. 1.

FIG. 15 is a block diagram illustrating an example of a refresh clock generator included in a master memory device, a slave memory device and an auto-refresh memory device of FIG. 13.

FIG. 16 is a block diagram illustrating an example of the refresh clock generator of FIG. 15 when the refresh clock generator is integrated in a master memory device.

FIG. 17 is a block diagram illustrating an example of the refresh clock generator of FIG. 15 when the refresh clock generator is integrated in a slave memory device.

FIG. 18 is a block diagram illustrating an example of the refresh clock generator of FIG. 15 when the refresh clock generator is integrated in an auto-refresh memory device.

FIG. 19 is a block diagram illustrating a mobile system according to exemplary embodiments.

FIG. 20 is a block diagram illustrating a computing system according to exemplary embodiments.

### DETAILED DESCRIPTION OF THE EMBODIMENTS

Various example embodiments will be described more fully with reference to the accompanying drawings, in which some example embodiments are shown. The present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to limit the scope of the disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

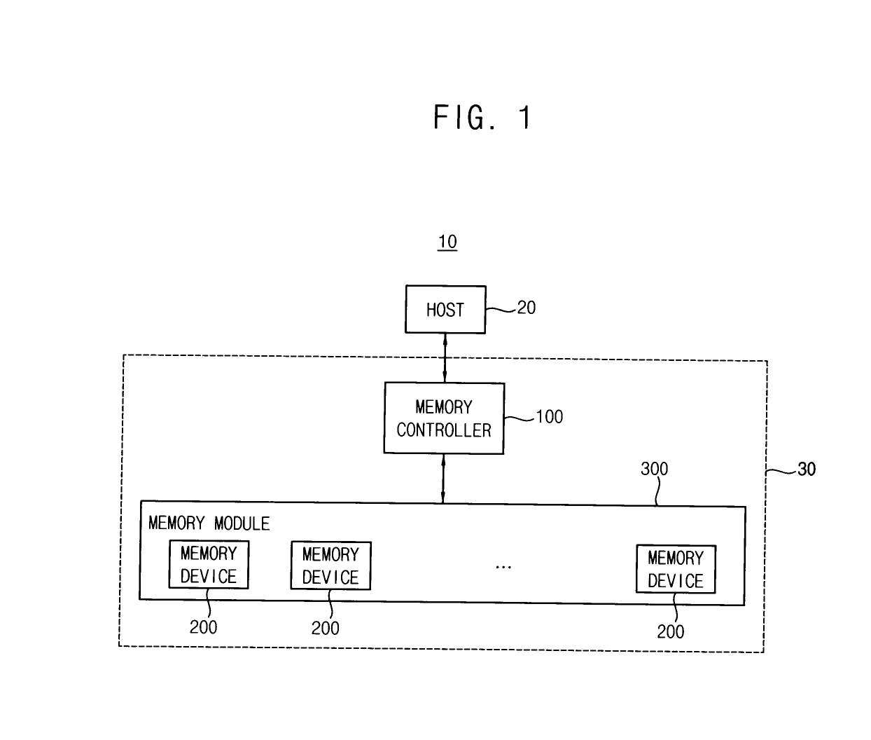

FIG. 1 is a block diagram illustrating an electronic system according to example embodiments.

Referring to FIG. 1, an electronic system 10 includes a host 20 and a memory system 30. The memory system 30 includes a memory controller 100 and a memory module 300. The memory module 300 includes a plurality of memory devices 200.

The host 20 may communicate with the memory system 30 through interface protocol such as Peripheral Component Interconnect-Express (PCI-E), Advanced Technology Attachment (ATA), Serial ATA (SATA), Parallel ATA (PATA), or serial attached SCSI (SAS). In addition, the host 20 may communicate with the memory system 30 through interface protocol such as Universal Serial Bus (USB), Multi-Media Card (MMC), Enhanced Small Disk Interface (ESDI), or Integrated Drive Electronics (IDE).

The memory controller 100 controls overall operation of the memory system 30. The memory controller 100 controls overall data exchange between the host 20 and the memory devices 200. For example, the memory controller 100 writes data to the memory devices 200 or reads data from the memory devices 200 in response to request from the host 20.

In addition, the memory controller 100 applies operation command to the memory devices 200 to control the memory devices 200.

In some embodiments, each of the memory devices 200 may be a dynamic random access memory (DRAM), such as a double data rate synchronous dynamic random access memory (DDR SDRAM), a low power double data rate synchronous dynamic random access memory (LPDDR SDRAM), a graphics double data rate synchronous dynamic random access memory (GDDR SDRAM), a Rambus dynamic random access memory (RDRAM), etc., or may be another volatile memory device.

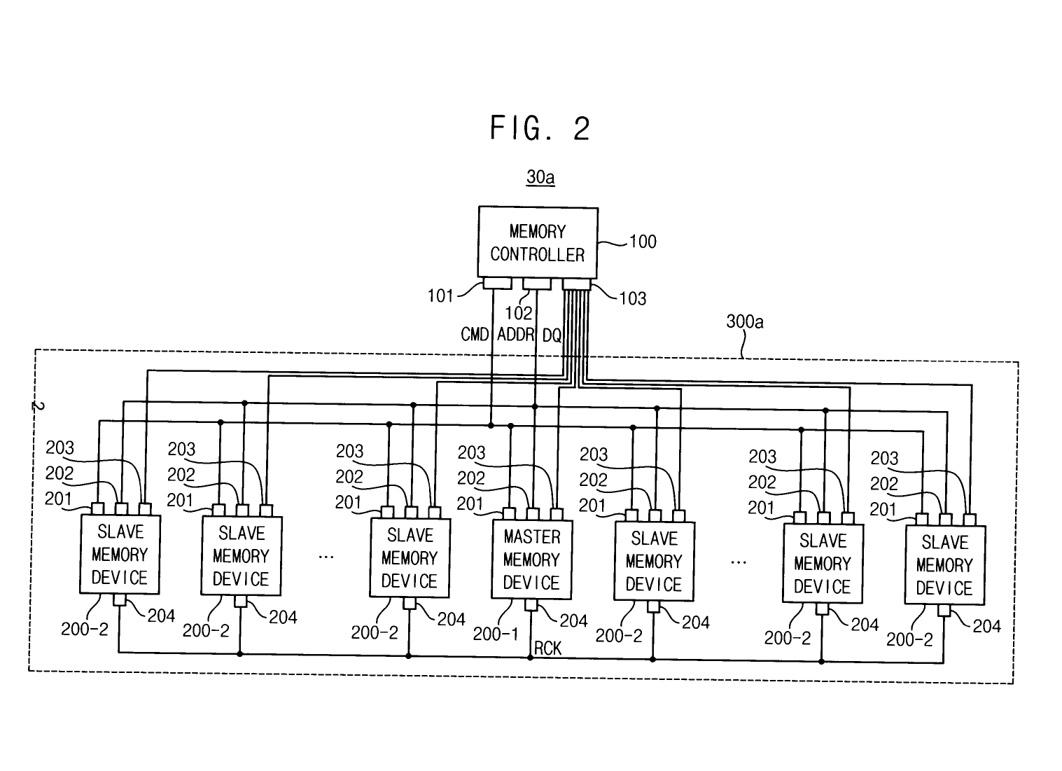

FIG. 2 is a block diagram illustrating an example of a memory system of FIG. 1 according to example embodiments.

Referring to FIG. 2, the memory system 30a may include a memory controller 100 and a memory module 300a. The memory module 300a may include one master memory device 200-1 and a plurality of slave memory devices 200-2.

The memory controller 100 may include a command pin 101, an address pin 102 and a data pin 103. Each of the master memory device 200-1 and the slave memory devices 200-2 may include a command pin 201, an address pin 202 and a data pin 203.

The command pin 101 of the memory controller 100 may be coupled to the command pins 201 of the master memory device 200-1 and the plurality of slave memory devices 200-2 in a multi-drop topology through a command bus. Therefore, the master memory device 200-1 and the plurality of slave memory devices 200-2 may receive a same command signal CMD from the memory controller 100.

The address pin 102 of the memory controller 100 may be coupled to the address pins 202 of the master memory device 200-1 and the plurality of slave memory devices 200-2 in a multi-drop topology through an address bus. Therefore, the master memory device 200-1 and the plurality of slave memory devices 200-2 may receive a same address signal ADDR from the memory controller 100.

The data pin 103 of the memory controller 100 may be coupled to the data pins 203 of the master memory device 200-1 and the plurality of slave memory devices 200-2 in a point-to-point topology through a data bus. Therefore, each of the master memory device 200-1 and the slave memory devices 200-2 may receive different data DQ from each other from the memory controller 100.

Therefore, the memory controller 100 may perform a read operation or a write operation on a same address of each of the master memory device 200-1 and the plurality of slave memory devices 200-2 at the same time.

Each of the master memory device 200-1 and the plurality of slave memory devices 200-2 may perform a refresh operation internally in a normal access mode as well as in a power down mode. Therefore, the memory controller 100 may not provide a refresh command to the master memory device 200-1 and the plurality of slave memory devices 200-2 regardless of an operation mode.

The master memory device 200-1 may generate a refresh clock signal RCK and provide the refresh clock signal RCK to the plurality of slave memory devices 200-2. The master memory device 200-1 and the plurality of slave memory devices 200-2 may perform the refresh operation in synchronization with the refresh clock signal RCK. That is, the master memory device 200-1 and the plurality of slave memory devices 200-2 may perform the refresh operation synchronously at the same time.

Each of the master memory device 200-1 and the plurality of slave memory devices 200-2 may include a refresh pin 204. The master memory device 200-1 and the plurality of slave memory devices 200-2 may transmit and/or receive the refresh clock signal RCK through a refresh sideband bus coupled to the refresh pins 204. For example, as illustrated in FIG. 2, the refresh pin 204 of the master memory device 200-1 may be coupled to the refresh pins 204 of the plurality of slave memory devices 200-2 in a multi-drop topology through the refresh sideband bus. In this case, the master memory device 200-1 may directly provide the refresh clock signal RCK to each of the plurality of slave memory devices 200-2 through the refresh pin 204.

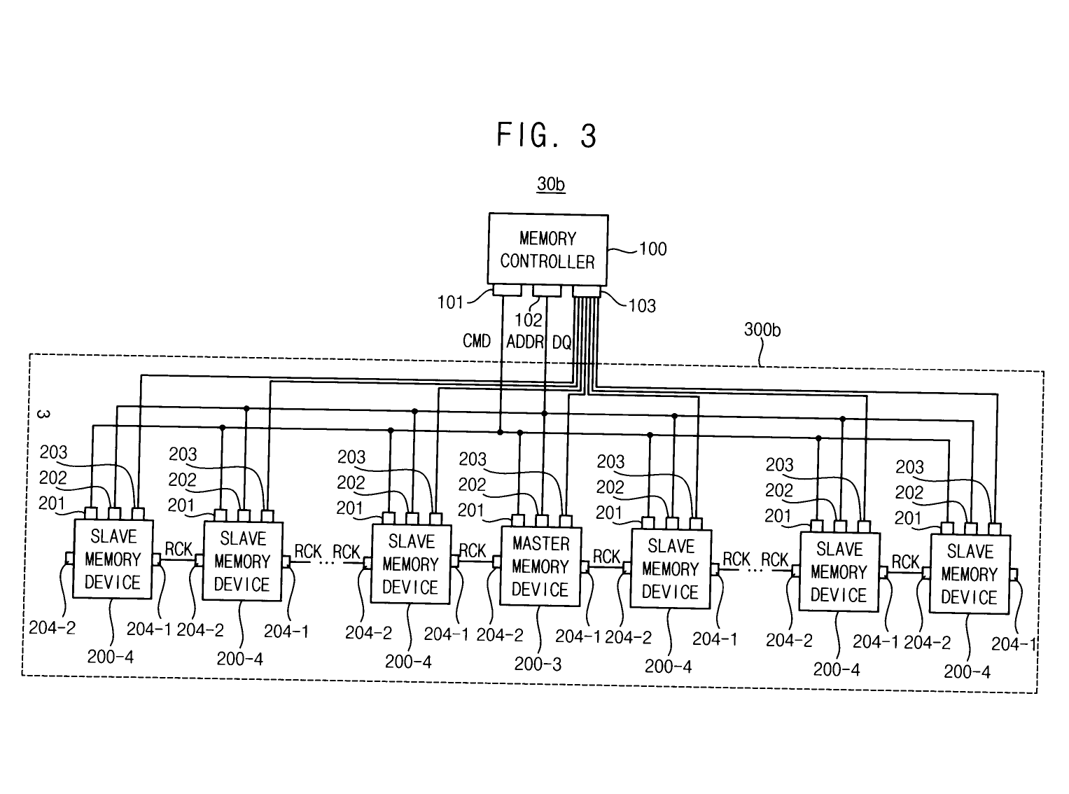

FIG. 3 is a block diagram illustrating another example of a memory system of FIG. 1 according to example embodiments.

Referring to FIG. 3, the memory system 30b may include a memory controller 100 and a memory module 300b. The memory module 300b may include one master memory device 200-3 and a plurality of slave memory devices 200-4.

The memory system 30b of FIG. 3 is the same as the memory system 30a of FIG. 2 except that each of the master memory device 200-3 and the plurality of slave memory devices 200-4 included in the memory system 30b includes a first refresh pin 204-1 and a second refresh pin 204-2 while each of the master memory device 200-1 and the plurality of slave memory devices 200-2 included in the memory system 30a includes one refresh pin 204. Therefore, duplicated description will be omitted.

Each of the master memory device 200-3 and the plurality of slave memory devices 200-4 may transmit and/or receive the refresh clock signal RCK through a refresh sideband bus coupled to the first refresh pin 204-1 and the second refresh pin 204-2. For example, as illustrated in FIG. 3, the first refresh pins 204-1 and the second refresh pins 204-2 of the master memory device 200-3 and the plurality of slave memory devices 200-4 may be coupled to each other in a daisy-chain topology through the refresh sideband bus. In this case, the first refresh pin 204-1 and the second refresh pin 204-2 may be internally coupled to each other in each of the master memory device 200-3 and the plurality of slave memory devices 200-4. The master memory device 200-3 may provide the refresh clock signal RCK to a slave memory device 200-4 adjacent to the master memory device 200-3 through the first refresh pin 204-1 and the second refresh pin 204-2, and each of the plurality of slave memory devices 200-4 may successively transmit the refresh clock signal RCK to an adjacent slave memory device 200-4 through the first refresh pin 204-1 and the second refresh pin 204-2.

The memory module 300a of FIG. 2 is the same as the memory module 300b of FIG. 3 except for the method of transmitting the refresh clock signal RCK between the master memory device 200-3 and the plurality of slave memory devices 200-4. Therefore, the structure and the operation of the memory module 300a of FIG. 2 described below may be applicable to the structure and the operation of the memory module 300b of FIG. 3.

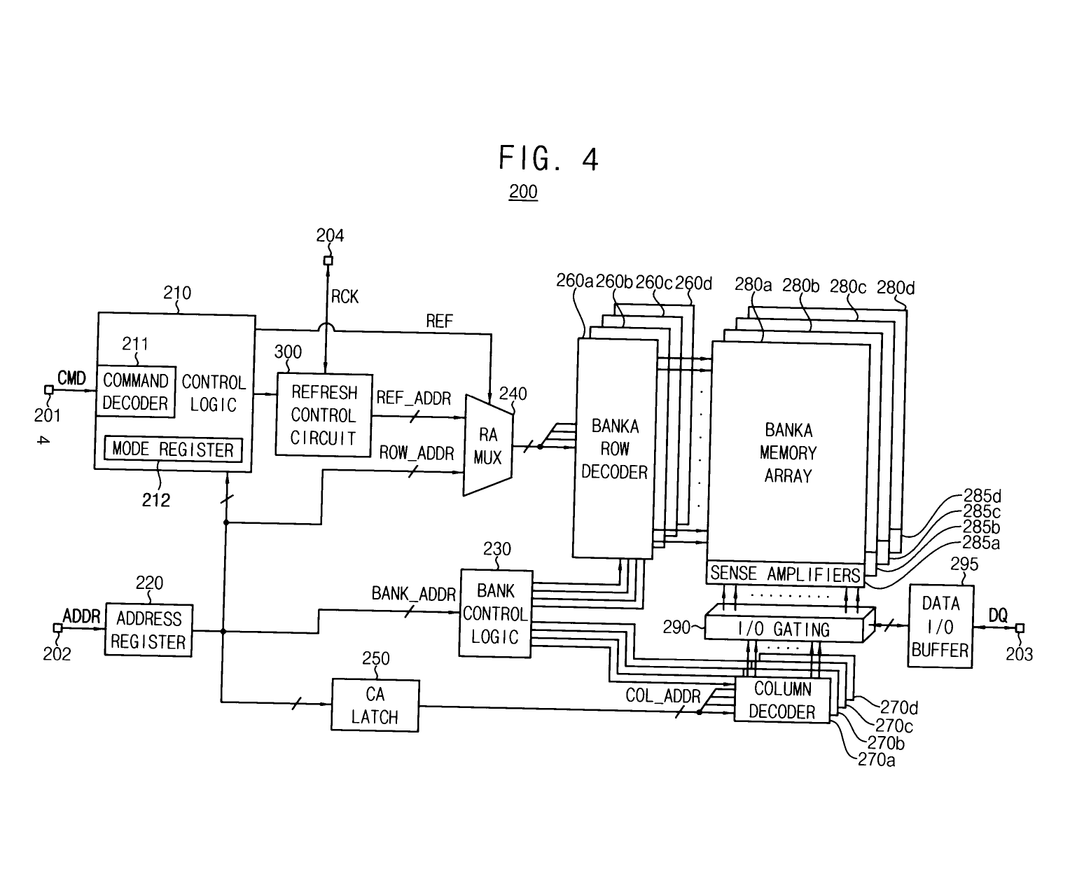

FIG. 4 is a block diagram illustrating an example of a memory device included in the memory module of FIG. 2 according to example embodiments.

Referring to FIG. 4, the memory device 200 may include a control logic 210, an address register 220, a bank control logic 230, a row address multiplexer 240, a column address latch 250, a row decoder, a column decoder, a memory cell array, a sense amplifier circuit, an input/output gating circuit 290, a data input/output buffer 295 and a refresh control circuit 300.

The master memory device 200-1 and the plurality of slave memory devices 200-2 included in the memory module 300a of FIG. 2 may be integrated in the memory device 200 of FIG. 4. As will be described below, the memory device 200 of FIG. 4 may selectively be used as one of the master memory device 200-1 and the slave memory device 200-2 according to the inner configuration of the refresh control circuit 300.

The memory cell array may include first through fourth bank arrays 280a, 280b, 280c and 280d. The row decoder may include first through fourth bank row decoders 260a, 260b, 260c and 260d respectively coupled to the first through fourth bank arrays 280a, 280b, 280c and 280d. The column decoder may include first through fourth bank column decoders 270a, 270b, 270c and 270d respectively coupled to the first through fourth bank arrays 280a, 280b, 280c and 280d. The sense amplifier circuit may include first through fourth bank sense amplifiers 285a, 285b, 385c and 385d respectively coupled to the first through fourth bank arrays 280a, 280b, 280c and 280d.

The first through fourth bank arrays 280a, 280b, 280c and 280d, the first through fourth bank row decoders 260a, 260b, 260c and 260d, the first through fourth bank column decoders 270a, 270b, 270c and 270d and the first through fourth bank sense amplifiers 285a, 285b, 285c and 285d may form first through fourth banks respectively. Although the memory device 200 includes four banks in FIG. 4, the memory device 200 may include any number of banks

The control logic 210 may control operations of the memory device 200. For example, the control logic 210 may generate control signals for the memory device 200 to perform a write operation or a read operation. The control logic 210 may include a command decoder 211 that decodes the command signal CMD received from the memory controller 100 through the command pin 201 and a mode register 212 that is used to set an operation mode of the memory device 200. For example, the command decoder 211 may generate the control signals corresponding to the command signal CMD by decoding a write enable signal (/WE), a row address strobe signal (/RAS), a column address strobe signal (/CAS), a chip select signal (/CS), etc. The control logic 210 may further receive a clock signal (CLK) and a clock enable signal (/CKE) for operating the memory device 200 in a synchronous manner.

The control logic 210 may control the refresh control circuit 300 such that the refresh control circuit 300 generates a refresh row address REF_ADDR on which a refresh operation is performed both in the power down mode and in the normal access mode. That is, the control logic 210 may control the refresh control circuit 300 such that the refresh control circuit 300 generates the refresh row address REF_ADDR regardless of the operation mode of the memory device. In addition, the control logic 210 may output an activated refresh signal REF while performing the refresh operation and output a deactivated refresh signal REF after finishing the refresh operation.

The refresh control circuit 300 included in the master memory device 200-1 may generate the refresh clock signal RCK, output the refresh clock signal RCK through the refresh pin 204, and generate the refresh row address REF_ADDR based on the refresh clock signal RCK.

The refresh control circuit 300 included in the slave memory device 200-2 may receive the refresh clock signal RCK through the refresh pin 204 and generate the refresh row address REF_ADDR based on the refresh clock signal RCK.

A structure and an operation of the refresh control circuit 300 will be described below with reference to FIGS. 5 to 8.

The address register 220 may receive the address signal ADDR including a bank address BANK_ADDR, a row address ROW_ADDR and a column address COL_ADDR from the memory controller 100 through the address pin 202. The address register 220 may provide the bank address BANK_ADDR to the bank control logic 230, provide the row address ROW_ADDR to the row address multiplexer 240, and provide the column address COL_ADDR to the column address latch 250.

The bank control logic 230 may generate bank control signals in response to the bank address BANK_ADDR. One of the first through fourth bank row decoders 260a, 260b, 260c and 260d corresponding to the bank address BANK_ADDR may be activated in response to the bank control signals, and one of the first through fourth bank column decoders 270a, 270b, 270c and 270d corresponding to the bank address BANK_ADDR may be activated in response to the bank control signals.

The row address multiplexer 240 may receive the row address ROW_ADDR from the address register 220 and receive the refresh row address REF_ADDR from the refresh control circuit 300. The row address multiplexer 240 may output one of the row address ROW_ADDR and the refresh row address REF_ADDR in response to the refresh signal REF received from the control logic 210. For example, the row address multiplexer 240 may output the refresh row address REF_ADDR when the refresh signal REF is activated, and output the row address ROW_ADDR when the refresh signal REF is deactivated. A row address output from the row address multiplexer 240 may be applied to the first through fourth bank row decoders 260a, 260b, 260c and 260d.

The activated one of the first through fourth bank row decoders 260a, 260b, 260c and 260d may decode the row address received from the row address multiplexer 240 and activate a word line corresponding to the row address. For example, the activated bank row decoder may apply a word line driving voltage to the word line corresponding to the row address.

The column address latch 250 may receive the column address COL_ADDR from the address register 220 and temporarily store the received column address COL_ADDR. In some embodiments, in a burst mode, the column address latch 250 may generate column addresses that increment from the received column address COL_ADDR. The column address latch 250 may apply the temporarily stored or generated column address to the first through fourth bank column decoders 270a, 270b, 270c and 270d.

The activated one of the first through fourth bank column decoders 270a, 270b, 270c and 270d may decode the column address COL_ADDR received from the column address latch 250 and control the input/output gating circuit 290 to output data corresponding to the column address COL_ADDR.

The input/output gating circuit 290 may include a circuitry for gating input/output data. The input/output gating circuit 290 may further include an input data mask logic, read data latches for storing data received from the first through fourth bank arrays 280a, 280b, 280c and 280d, and write drivers for writing data to the first through fourth bank arrays 280a, 280b, 280c and 280d.

Data DQ to be read from one bank array of the first through fourth bank arrays 280a, 280b, 280c and 280d may be sensed by a sense amplifier coupled to the one bank array and be stored in the read data latches. The data DQ stored in the read data latches may be provided to the memory controller 100 via the data input/output buffer 295 and the data pin 203. Data DQ to be written to one bank array of the first through fourth bank arrays 280a, 280b, 280c and 280d may be provided from the memory controller 100 to the data input/output buffer 295 via the data pin 203. The data DQ provided to the data input/output buffer 295 may be written to the one bank array via the write drivers.

FIG. 5 is a block diagram illustrating an example of a refresh control circuit included in the memory device of FIG. 4.

Referring to FIG. 5, the refresh control circuit 300 may include a refresh clock generator 310 and a refresh counter 320.

The refresh clock generator 310 included in the master memory device 200-1 may generate the refresh clock signal RCK, output the refresh clock signal RCK through the refresh pin 204, and provide the refresh clock signal RCK to the refresh counter 320.

The refresh clock generator 310 included in the slave memory device 200-2 may not generate the refresh clock signal RCK but receive the refresh clock signal RCK, which is generated from the master memory device 200-1, through the refresh pin 204, and provide the refresh clock signal RCK to the refresh counter 320.

The refresh counter 320 may generate the refresh row address REF_ADDR in response to the refresh clock signal RCK by incrementing the refresh row address REF_ADDR every cycle of the refresh clock signal RCK. The control logic 210 may provide a reset signal RST to the refresh counter 320 at start-up, and the refresh counter 320 may reset the refresh row address REF_ADDR in response to the reset signal RST.

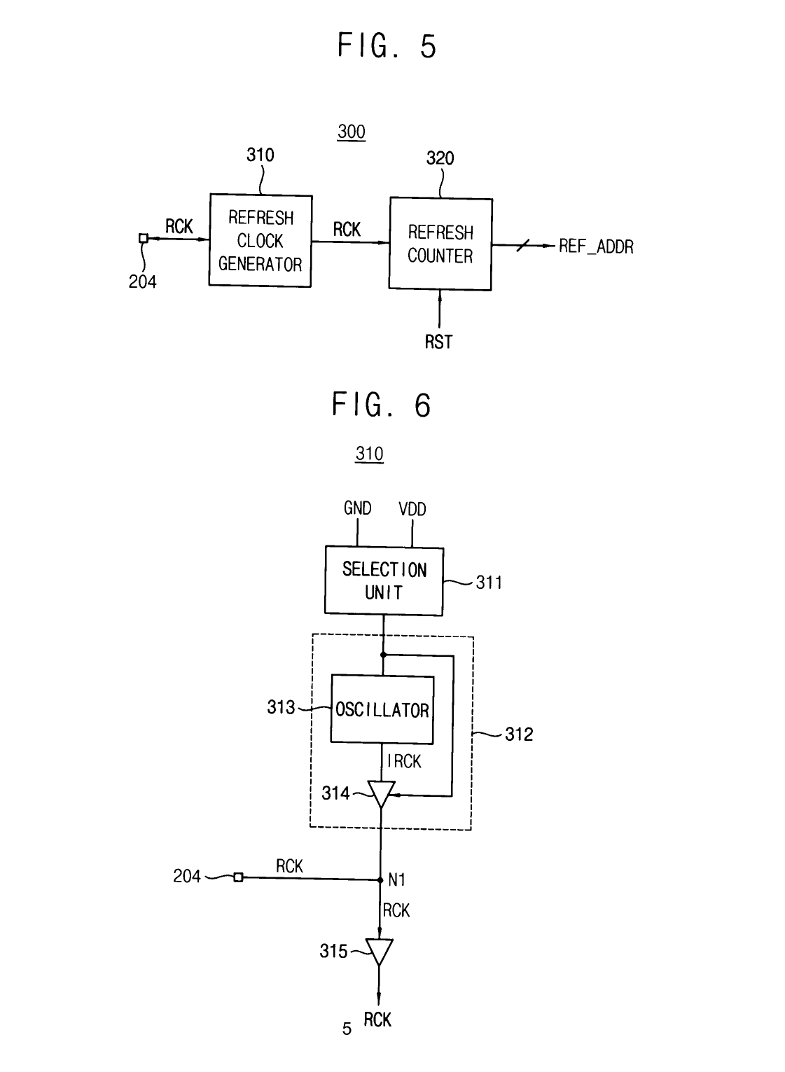

FIG. 6 is a block diagram illustrating an example of a refresh clock generator included in the refresh control circuit of FIG. 5.

Referring to FIG. 6, the refresh clock generator 310 may include a selection unit 311, an oscillation unit 312 and a buffer unit 315.

The selection unit 311 may receive a first voltage and a second voltage. The first voltage may be a ground voltage GND and the second voltage may be a supply voltage VDD. The selection unit 311 may selectively output one of the first voltage GND and the second voltage VDD.

When the oscillation unit 312 receives the supply voltage VDD from the selection unit 311, the oscillation unit 312 may be enabled such that the oscillation unit 312 may generate the refresh clock signal RCK and provide the refresh clock signal RCK to a first node N1 to which the refresh pin 204 is coupled. When the oscillation unit 312 receives the ground voltage GND from the selection unit 311, the oscillation unit 312 may be disabled such that the oscillation unit 312 may not generate the refresh clock signal RCK.

The oscillation unit 312 may include an oscillator 313 and a buffer 314. When the oscillator 313 and the buffer 314 receives the supply voltage VDD from the selection unit 311, the oscillator 313 and the buffer 314 may be enabled such that the oscillator 313 may generate an inner refresh clock signal IRCK and the buffer 314 may buffer the inner refresh clock signal IRCK and output the inner refresh clock signal IRCK as the refresh clock signal RCK. When the oscillator 313 and the buffer 314 receives the ground voltage GND from the selection unit 311, the oscillator 313 and the buffer 314 may be disabled such that the oscillator 313 may not generate the inner refresh clock signal IRCK and the buffer 314 may not output the refresh clock signal RCK.

The buffer unit 315 may buffer the refresh clock signal RCK received from the first node N1 and output the refresh clock signal RCK.

When the selection unit 311 outputs the supply voltage VDD, the memory device 200 may operate as the master memory device 200-1. When the selection unit 311 outputs the ground voltage GND, the memory device 200 may operate as a slave memory device 200-2.

In some example embodiments, the selection unit 311 may include a first fuse circuit coupled to the ground voltage GND and a second fuse circuit coupled to the supply voltage VDD, and selectively output one of the ground voltage GND and the supply voltage VDD by cutting one of the first fuse circuit and the second fuse circuit.

For example, the selection unit 311 included in the master memory device 200-1 may output the supply voltage VDD by cutting the first fuse circuit, and the selection unit 311 included in the slave memory device 200-2 may output the ground voltage GND by cutting the second fuse circuit. In this case, one of the first fuse circuit and the second fuse circuit included in the selection unit 311 may be cut during a manufacturing process of the memory device 200 to determine the memory device 200 as one of the master memory device 200-1 and the slave memory device 200-2.

In other example embodiments, the selection unit 311 may include a switch selectively connected to one of the ground voltage GND and the supply voltage VDD according to a configuration value that is programmed from outside of the selection unit 311. The selection unit 311 may output the ground voltage GND when the configuration value corresponds to a first value and output the supply voltage VDD when the configuration value corresponds to a second value.

For example, the configuration value of the selection unit 311 included in the master memory device 200-1 may be programmed as the second value such that the selection unit 311 may output the supply voltage VDD, and the configuration value of the selection unit 311 included in the slave memory device 200-2 may be programmed as the first value such that the selection unit 311 may output the ground voltage GND. In this case, the memory device 200 may be determined as one of the master memory device 200-1 and the slave memory device 200-2 according to the program. The program is provided after the memory device 200 is manufactured.

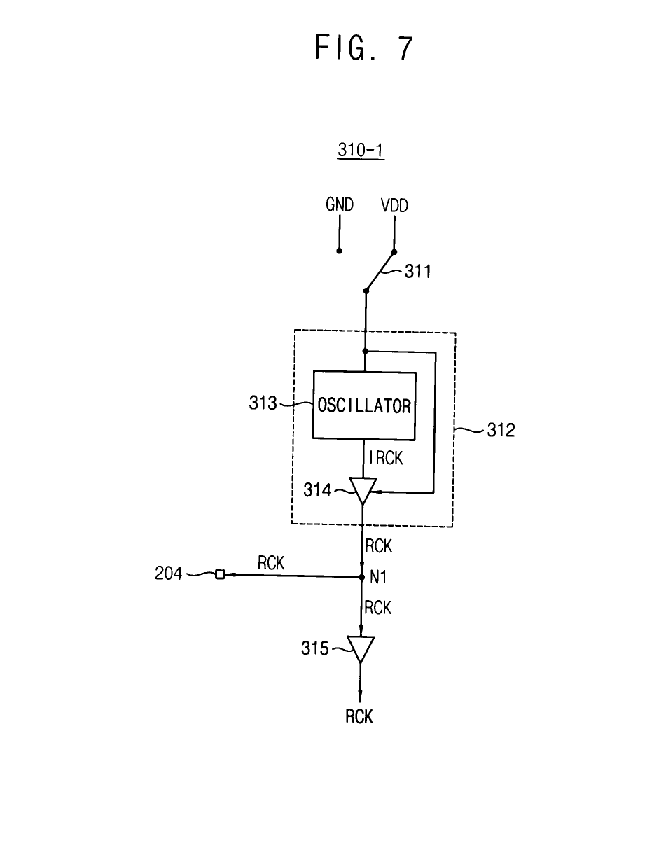

FIG. 7 is a block diagram illustrating an example of the refresh clock generator of FIG. 6 when the refresh clock generator is included in a master memory device.

Referring to FIG. 7, the selection unit 311 of the refresh clock generator 310-1 included in the master memory device 200-1 may output the supply voltage VDD. Therefore, the oscillation unit 312 may generate the refresh clock signal RCK and provide the refresh clock signal RCK to the plurality of slave memory devices 200-2 through the refresh pin 204. The buffer unit 315 may output the refresh clock signal RCK received from the oscillation unit 312.

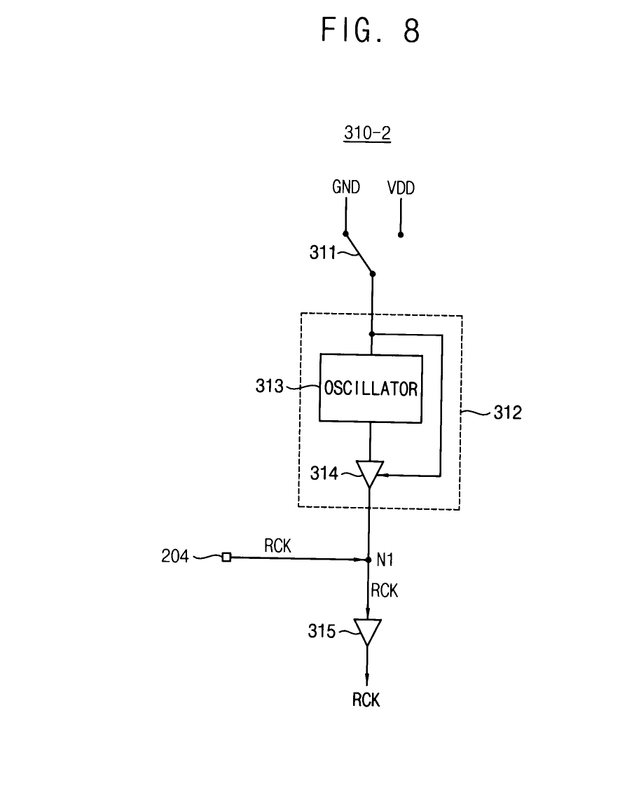

FIG. 8 is a block diagram illustrating an example of the refresh clock generator of FIG. 6 when the refresh clock generator is included in a slave memory device.

Referring to FIG. 8, the selection unit 311 of the refresh clock generator 310-2 included in the slave memory device 200-2 may output the ground voltage GND. Therefore, the oscillation unit 312 may not generate the refresh clock signal RCK. Since the refresh clock signal RCK generated from the master memory device 200-1 is provided to the first node N1 through the refresh pin 204, the buffer unit 315 may output the refresh clock signal RCK received from the first node N1.

As described above, the memory device 200 may selectively operate as one of the master memory device 200-1 and the slave memory device 200-2 based on an inner configuration of the selection unit 311 included in the refresh clock generator 310. Therefore, the manufacturing process of the memory module 300 may be simplified.

Since all of the master memory device 200-1 and the plurality of slave memory devices 200-2 included in the memory module 300 perform the refresh operation in synchronization with the refresh clock signal RCK generated from the master memory device 200-1, a memory device having a shortest refresh period among the memory devices included in the memory module 300 may be selected as the master memory device 200-1 and the rest of the memory devices included in the memory module 300 may be chosen as the salve memory devices 200-2.

As described above, the master memory device 200-1 and each of the plurality of slave memory devices 200-2 may perform the refresh operation internally in the normal access mode as well as in the power down mode without receiving the refresh command from the memory controller 100. Therefore, in the normal access mode, the master memory device 200-1 and each of the plurality of slave memory devices 200-2 may receive a read command or a write command on a row address included in a memory block from the memory controller 100 while internally performing the refresh operation on a row address included in the same memory block such that the read command or the write command is conflicted with the refresh operation.

Hereinafter, an operation of the memory device 200 for resolving the conflict between a read operation or a write operation performed by a command from the memory controller 100 and the refresh operation performed internally in the memory device 200 will be described with reference to FIGS. 1 to 10. The memory device 200 may operate as either the master memory device 200-1 or one of the slave memory devices 200-2.

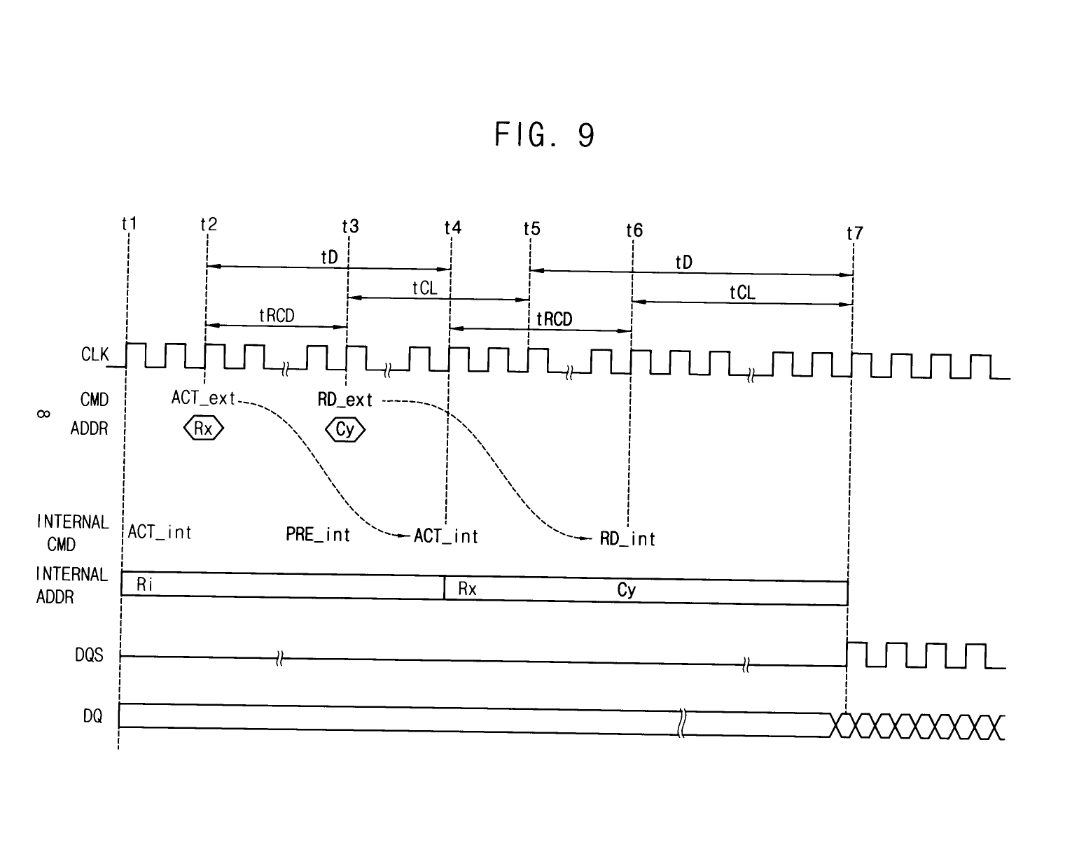

FIG. 9 is a timing diagram for describing an operation of a memory device included in a memory system of FIG. 1 for resolving a conflict between a read operation and a refresh operation.

Referring to FIG. 9, at a time t1, the control logic 210 may generate an active command ACT_int as an internal command INTERNAL CMD to internally perform the refresh operation, the refresh control circuit 300 may generate a refresh row address Ri, and the row address multiplexer 240 may apply the refresh row address Ri on an internal address bus INTERNAL ADDR. Therefore, the memory device 200 may perform the refresh operation on a row corresponding to the refresh row address Ri. After finishing the refresh operation, the control logic 210 may generate a precharge command PRE_int as the internal command INTERNAL CMD to precharge bit lines of the memory cell array.

At a time t2, the memory device 200 may receive an active command ACT_ext through the command pin 201 and receive a row address Rx through the address pin 202 from the memory controller 100. At a time t3, which is after a row address-to-column address delay tRCD from the time t2, the memory device 200 may receive a read command RD_ext through the command pin 201 and receive a column address Cy through the address pin 202 from the memory controller 100.

If the refresh row address Ri and the row address Rx are included in a same memory block of the memory cell array, the memory device 200 may not activate a row corresponding to the row address Rx while performing the refresh operation on the row corresponding to the refresh row address Ri. Therefore, at a time t4, which is after the refresh operation on the row corresponding to the refresh row address Ri is finished and the bit lines of the memory cell array are precharged, the memory device 200 may generate an active command ACT_int corresponding to the active command ACT_ext as an internal command INTERNAL CMD and apply the row address Rx on the internal address bus INTERNAL ADDR to activate the row corresponding to the row address Rx. In addition, at a time t6, which is after the row address-to-column address delay tRCD from the time t4, the memory device 200 may generate a read command RD_int corresponding to the read command RD_ext as the internal command INTERNAL CMD and apply the column address Cy on the internal address bus INTERNAL ADDR to perform the read operation on a column corresponding to the column address Cy.

As described above, when a conflict between the read operation performed by a command from the memory controller 100 and the refresh operation performed internally occurs, the memory device 200 may delay the read operation by a delay time tD, which corresponds to a duration from the time t2 at which the active command ACT_ext is received to the time t4 at which the refresh operation is finished and the bit lines of the memory cell array are precharged, such that the memory device 200 may perform the read operation after the refresh operation is finished and the bit lines of the memory cell array are precharged.

If the memory device 200 does not perform the refresh operation at the time t1 such that the memory device 200 performs the active command ACT_ext and the read command RD_ext immediately without the delay time tD, the memory device 200 may provide read data DQ to the memory controller 100 at a time t5, which is after a column address strobe (CAS) latency tCL from the time t3 at which the read command RD_ext is received. However, as described above, since the memory device 200 performs the refresh operation when the memory device 200 receives the active command ACT_ext at the time t2, the memory device 200 may delay the performance of the read operation by the delay time tD from the time t2. Therefore, the memory device 200 may provide read data DQ to the memory controller 100 at a time t7, which is after the column address strobe (CAS) latency tCL from the time t6 at which the read command RD_int is generated. As such, the memory device 200 may not provide a data strobe signal DQS to the memory controller 100 at the time t5 but provide the data strobe signal DQS together with the read data DQ to the memory controller 100 at the time t7.

In a read mode, the memory controller 100 may provide the active command ACT_ext and the read command RD_ext to the memory device 200 consecutively with the row address-to-column address delay tRCD, and wait until the data strobe signal DQS is provided from the memory device 200. When the memory controller 100 receives the data strobe signal DQS from the memory device 200, the memory controller 100 may receive the read data DQ by sampling the read data DQ in synchronization with the data strobe signal DQS.

As described above, when a conflict occurs between the read operation performed by a command from the memory controller 100 and the refresh operation performed internally, the memory device 200 may perform the read operation after finishing the refresh operation and provide the data strobe signal DQS together with the read data DQ to the memory controller 100, and the memory controller 100 may receive the read data DQ by sampling the read data DQ in synchronization with the data strobe signal DQS. As such, the memory system 30 may resolve the conflict between the read operation and the refresh operation.

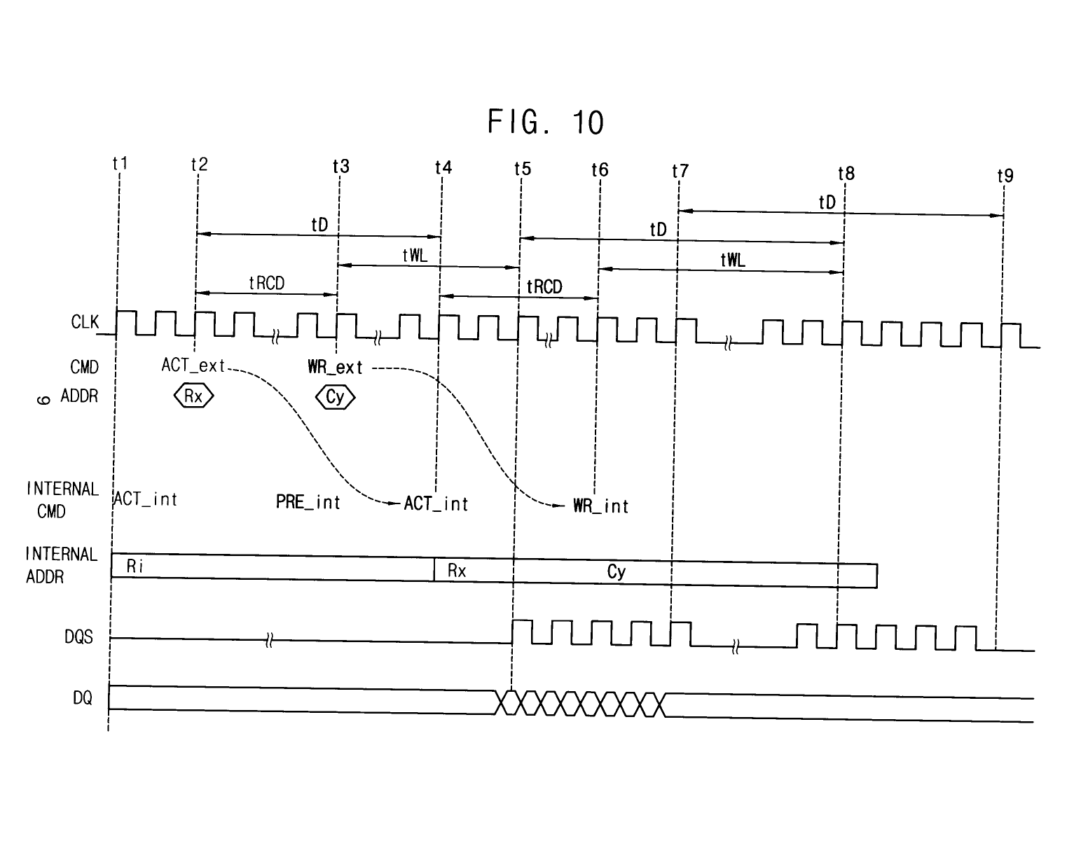

FIG. 10 is a timing diagram for describing an operation of a memory device included in a memory system of FIG. 1 for resolving a conflict between a write operation and a refresh operation.

Referring to FIG. 10, at a time t1, the control logic 210 may generate an active command ACT_int as an internal command INTERNAL CMD to internally perform the refresh operation, the refresh control circuit 300 may generate a refresh row address Ri, and the row address multiplexer 240 may apply the refresh row address Ri on an internal address bus INTERNAL ADDR. Therefore, the memory device 200 may perform the refresh operation on a row corresponding to the refresh row address Ri. After finishing the refresh operation, the control logic 210 may generate a precharge command PRE int as the internal command INTERNAL CMD to precharge bit lines of the memory cell array.

At a time t2, the memory device 200 may receive an active command ACT_ext through the command pin 201 and receive a row address Rx through the address pin 202 from the memory controller 100. At a time t3, which is after the row address-to-column address delay tRCD from the time t2, the memory device 200 may receive a write command WR_ext through the command pin 201 and receive a column address Cy through the address pin 202 from the memory controller 100. At a time t5, which is after a write latency tWL from the time t3, the memory device 200 may receive the data strobe signal DQS together with write data DQ through the data pin 203 from the memory controller 100. When a transmission of the write data DQ from the memory controller 100 to the memory device 200 is finished at a time t7, the memory controller 100 may stop providing the data strobe signal DQS to the memory device 200. Therefore, a toggling of the data strobe signal DQS provided from the memory controller 100 may stop at the time t7.

If the refresh row address Ri and the row address Rx are included in a same memory block of the memory cell array, the memory device 200 may not activate a row corresponding to the row address Rx while performing the refresh operation on the row corresponding to the refresh row address Ri. Therefore, at a time t4, which is after the refresh operation on the row corresponding to the refresh row address Ri is finished and the bit lines of the memory cell array are precharged, the memory device 200 may generate an active command ACT_int corresponding to the active command ACT_ext as an internal command INTERNAL CMD and apply the row address Rx on the internal address bus INTERNAL ADDR to activate the row corresponding to the row address Rx. At a time t6, which is after the row address-to-column address delay tRCD from the time t4, the memory device 200 may generate a write command WR_int corresponding to the write command WR_ext as an internal command INTERNAL CMD and apply the column address Cy on the internal address bus INTERNAL ADDR to perform the write operation on a column corresponding to the column address Cy.

As described above, when a conflict occurs between the write operation performed by a command from the memory controller 100 and the refresh operation performed internally, the memory device 200 may delay the write operation by a delay time tD, which corresponds to a duration from the time t2 at which the active command ACT_ext is received to the time t4 at which the refresh operation is finished and the bit lines of the memory cell array are precharged, such that the memory device 200 may perform the write operation after the refresh operation is finished and the bit lines of the memory cell array are precharged.

If the memory device 200 does not perform the refresh operation at the time t1 such that the memory device 200 performs the active command ACT_ext and the write command WR_ext immediately without the delay time tD, the memory controller 100 may deem that the write operation finishes when a transmission of the write data DQ from the memory controller 100 to the memory device 200 finishes at the time t7. However, as described above, since the memory device 200 performs the refresh operation when the memory device 200 receives the active command ACT_ext at the time t2, the memory device 200 may delay the performance of the write operation by the delay time tD from the time t2. Therefore, the memory device 200 may continuously toggle the data strobe signal DQS, which is provided from the memory device 200 to the memory controller 100, from the time t7 at which a toggling of the data strobe signal DQS provided from the memory controller 100 stops until a time t9 at which the performance of the write command finishes. Therefore, the write operation starts at time t8 after the write latency tWL from time t6 at which the internal write command WR_int is performed. The write operation is performed between t8 and t9. This is delayed by the delay time tD from the time that the memory controller 100 provides the data strobe signal DQS.

In a write mode, the memory controller 100 may provide the active command ACT_ext and the write command WR_ext to the memory device 200 consecutively with the row address-to-column address delay tRCD, and provide the data strobe signal DQS together with the write data DQ after the write latency tWL from a time at which the write command WR_ext is provided to the memory device 200. After that, when a toggling of the data strobe signal DQS provided from the memory device 200 stops, the memory controller 100 may deem that the write operation on the memory device 200 has finished.

As described above, when a conflict occurs between the write operation performed by a command from the memory controller 100 and the refresh operation performed internally, the memory device 200 may perform the write operation after finishing the refresh operation and continuously toggle the data strobe signal DQS, which is provided from the memory device 200 to the memory controller 100, from a time at which a toggling of the data strobe signal DQS provided from the memory controller 100 stops until a time at which the performance of the write command finishes, and the memory controller 100 may deem that the write operation on the memory device 200 has finished when a toggling of the data strobe signal DQS provided from the memory device 200 stops. As such, the memory system 30 may resolve the conflict between the write operation and the refresh operation.

As described above with reference to FIGS. 1 to 10, the memory controller 100 may not provide the refresh command to the memory module 300 because the memory module 300 included in the memory system 30 includes the master memory device 200-1 and the plurality of slave memory devices 200-2 that internally perform the refresh operation without a conflict with the read operation or the write operation in the normal access mode as well as in the power down mode. Therefore, the memory system 30 may consume less power and increase efficiency of the command bus.

In addition, since the master memory device 200-1 and each of the plurality of slave memory devices 200-2 perform the refresh operation at the same time in synchronization with the refresh clock signal RCK generated from the master memory device 200-1, the memory controller 100 may efficiently manage the master memory device 200-1 and the plurality of slave memory devices 200-2 included in the memory module 300.

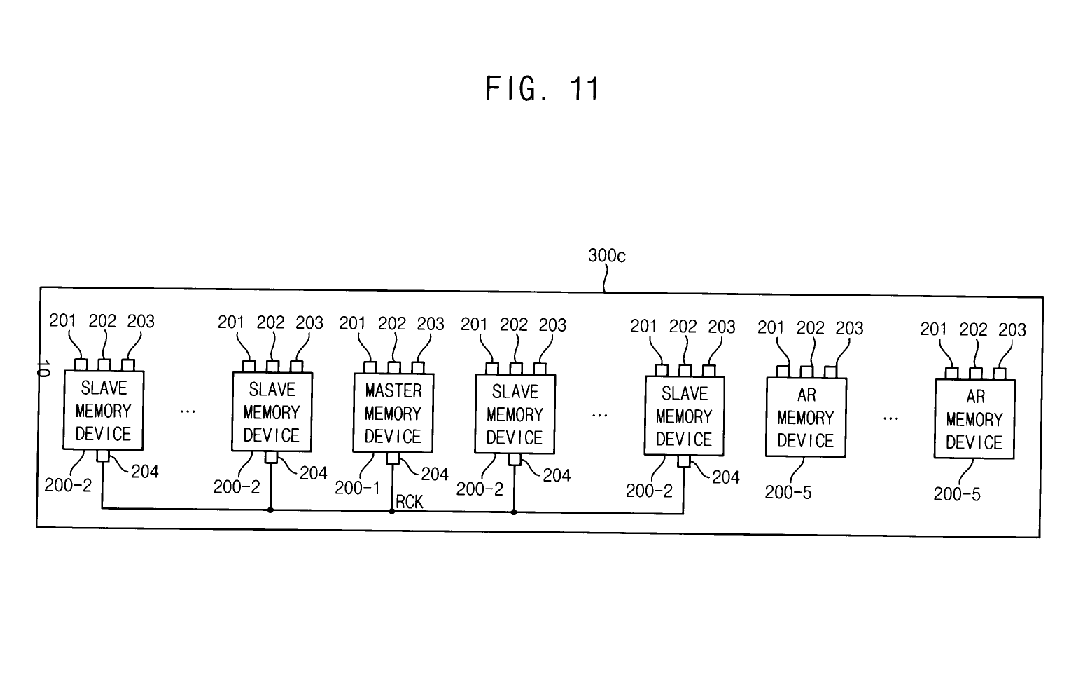

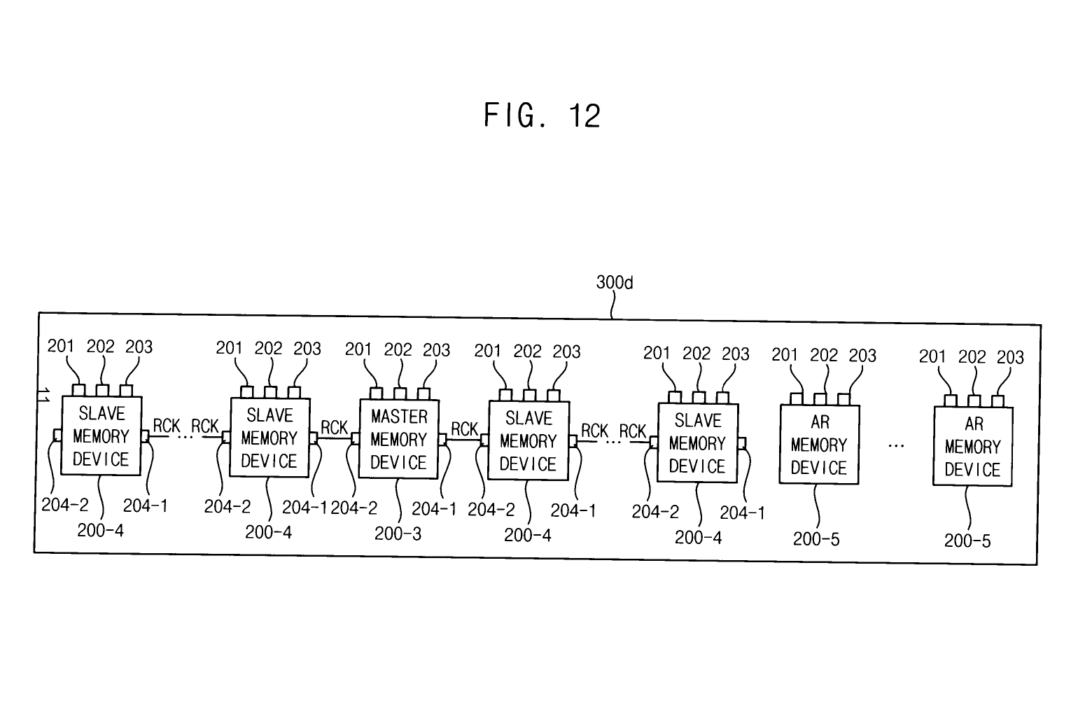

FIGS. 11 to 14 are block diagrams illustrating other examples of a memory module included in a memory system of FIG. 1.

Referring to FIG. 11, the memory module 300c may include one master memory device 200-1, a plurality of slave memory devices 200-2 and a plurality of auto-refresh memory devices 200-5.

The master memory device 200-1 and the plurality of slave memory devices 200-2 included in the memory module 300c of FIG. 11 may be the same as the master memory device 200-1 and the plurality of slave memory devices 200-2 included in the memory module 300a of FIG. 2. Therefore, duplicated description will be omitted.

Referring to FIG. 12, the memory module 300d may include one master memory device 200-3, a plurality of slave memory devices 200-4 and a plurality of auto-refresh memory devices 200-5.

The master memory device 200-3 and the plurality of slave memory devices 200-4 included in the memory module 300d of FIG. 12 may be the same as the master memory device 200-3 and the plurality of slave memory devices 200-4 included in the memory module 300b of FIG. 3. Therefore, duplicated description will be omitted.

Each of the plurality of auto-refresh memory devices 200-5 included in the memory module 300c of FIG. 11 and the memory module 300d of FIG. 12 may perform the refresh operation in response to a refresh command received from the memory controller 100. That is, each of the plurality of auto-refresh memory devices 200-5 may perform a self-refresh operation in the power down mode and perform an auto-refresh operation in response to the refresh command received from the memory controller 100 in the normal access mode. In addition, each the plurality of auto-refresh memory devices 200-5 may not perform the refresh operation in synchronization with the refresh clock signal RCK. Instead, each of the plurality of auto-refresh memory devices 200-5 may generate an inner refresh clock signal and perform the refresh operation in synchronization with the inner refresh clock signal when each of the plurality of auto-refresh memory devices 200-5 receives the refresh command from the memory controller 100. Therefore, each of the plurality of auto-refresh memory devices 200-5 may perform the refresh operation with a different refresh period from the master memory devices 200-1 and 200-3 and the plurality of slave memory devices 200-2 and 200-4.

In some example embodiments, the plurality of auto-refresh memory devices 200-5 may be included in a different rank from the master memory device 200-1 and 200-3 and the plurality of slave memory devices 200-2 and 200-4.

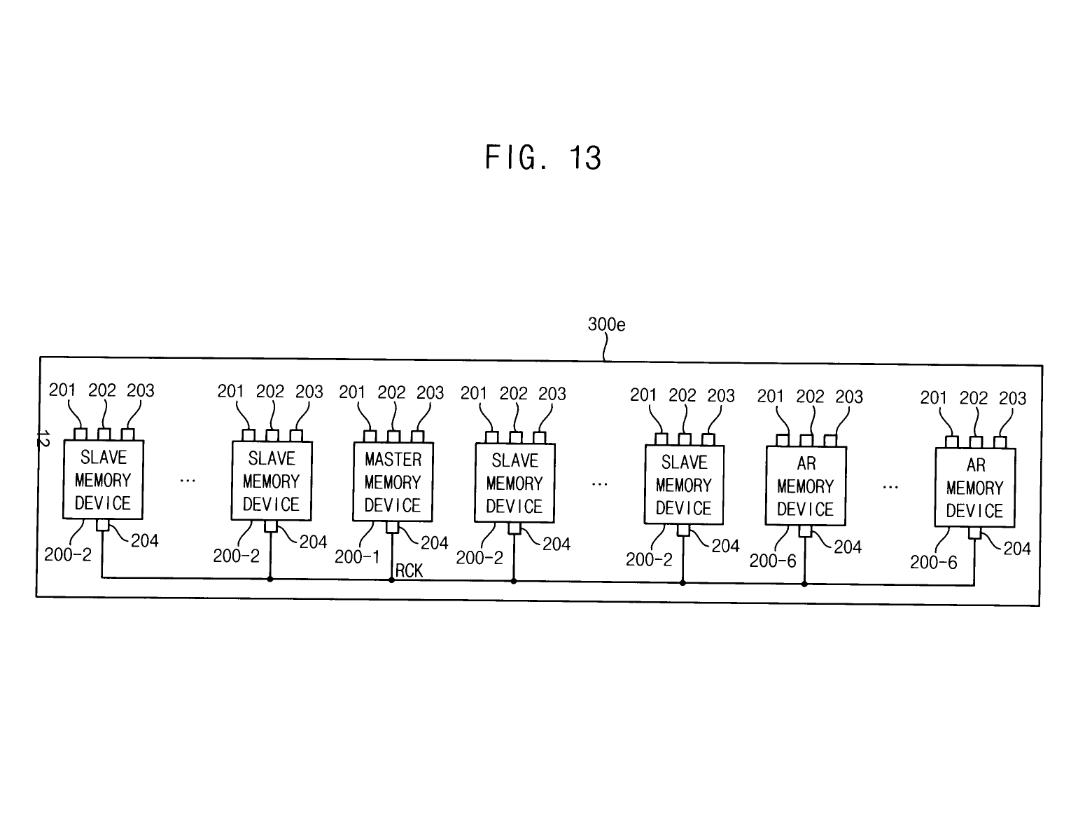

Referring to FIG. 13, the memory module 300e may include one master memory device 200-1, a plurality of slave memory devices 200-2 and a plurality of auto-refresh memory devices 200-6.

The master memory device 200-1, the plurality of slave memory devices 200-2 and the plurality of auto-refresh memory devices 200-6 may have the same structure. For example, the master memory device 200-1, the plurality of slave memory devices 200-2 and the plurality of auto-refresh memory devices 200-6 may be implemented with the memory device 200 of FIG. 4, and the memory device 200 of FIG. 4 may selectively operate as one of the master memory device 200-1, the slave memory device 200-2 and the auto-refresh memory devices 200-6 based on an inner configuration of the refresh clock generator 310. In addition, each of the plurality of auto-refresh memory devices 200-6 may receive the refresh clock signal RCK generated from the master memory device 200-1 through the refresh pin 204.

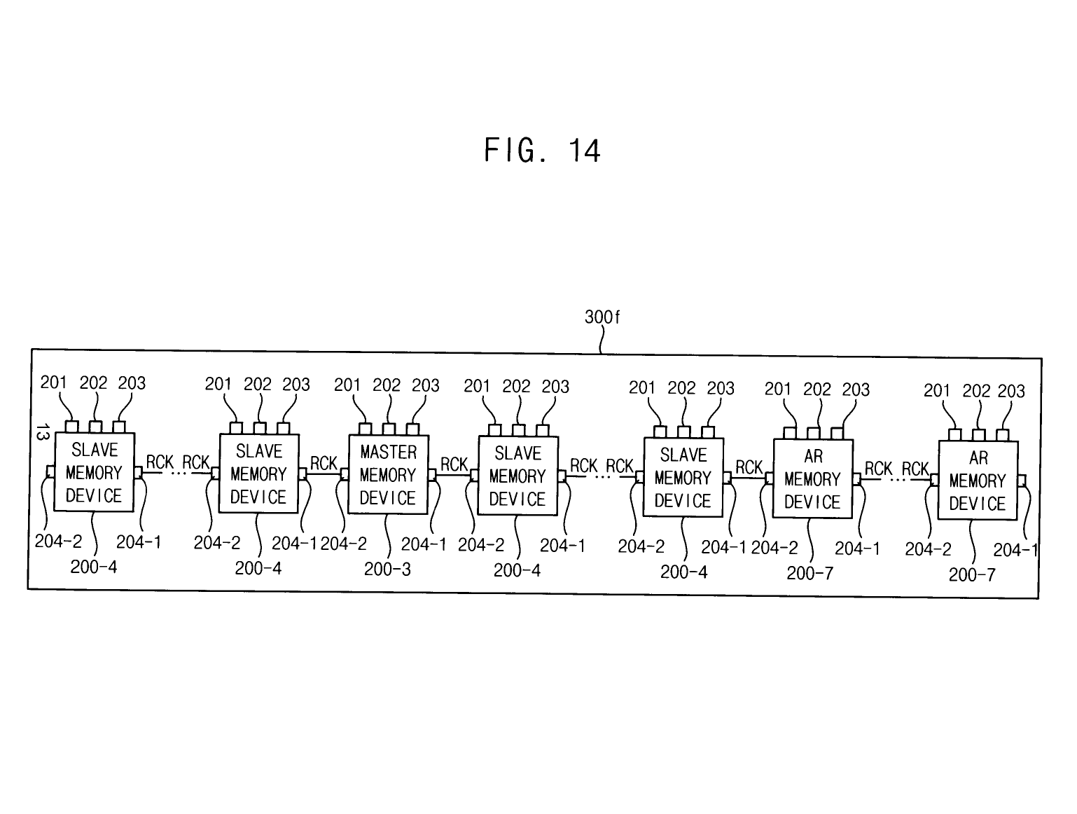

Referring to FIG. 14, the memory module 300f may include one master memory device 200-3, a plurality of slave memory devices 200-4 and a plurality of auto-refresh memory devices 200-7.

The master memory device 200-3, the plurality of slave memory devices 200-4 and the plurality of auto-refresh memory devices 200-7 may have the same structure except the inner configuration of the refresh clock generator 310. In addition, each of the master memory device 200-3, the plurality of slave memory devices 200-4 and the plurality of auto-refresh memory devices 200-7 included in the memory module 300f of FIG. 14 may have the same structure as each of the master memory device 200-1, the plurality of slave memory devices 200-2 and the plurality of auto-refresh memory devices 200-6 included in the memory module 300e of FIG. 13 except that the master memory device 200-3, the plurality of slave memory devices 200-4 and the plurality of auto-refresh memory devices 200-7 included in the memory module 300f of FIG. 14 may transmit and/or receive the refresh clock signal RCK through the first refresh pin 204-1 and the second refresh pin 204-2.

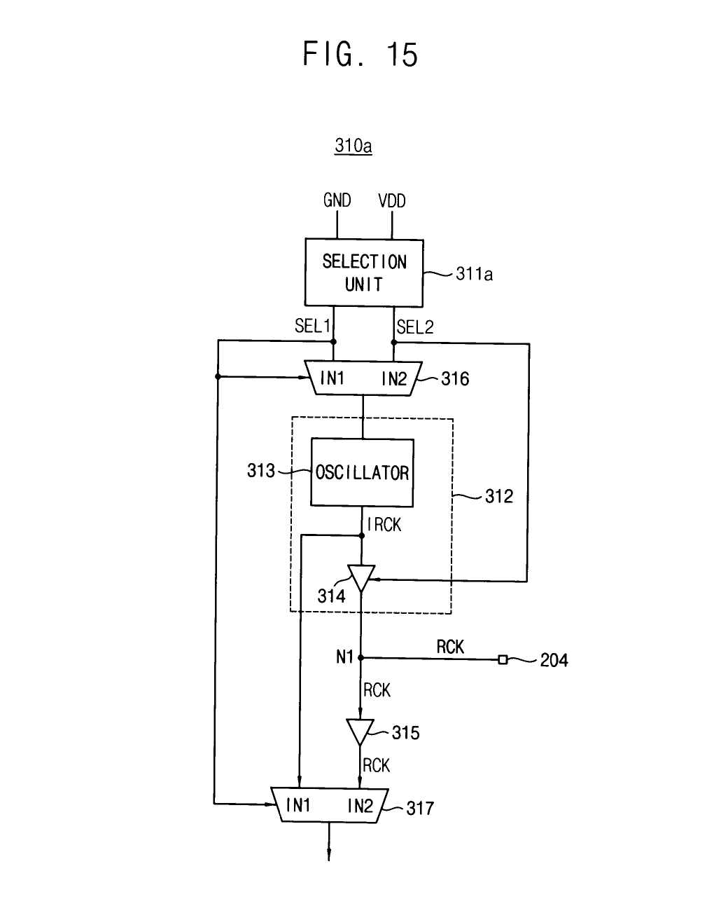

FIG. 15 is a block diagram illustrating an example of a refresh clock generator included in a master memory device, a slave memory device and an auto-refresh memory device of FIG. 13.

Referring to FIG. 15, the refresh clock generator 310a may include a selection unit 311a, an oscillation unit 312, a buffer unit 315, a first multiplexer 316 and a second multiplexer 317.

The selection unit 311a may receive a first voltage and a second voltage. The first voltage may be a ground voltage GND and the second voltage may be a supply voltage VDD. The selection unit 311a may generate a first selection signal SEL1 and a second selection signal SEL2 using the first voltage GND and the second voltage VDD. Each of the first selection signal SEL1 and the second selection signal SEL2 may have one of the first voltage GND and the second voltage VDD.

The first multiplexer 316 may receive the first selection signal SEL1 through a first input electrode IN1 and receive the second selection signal SEL2 through a second input electrode IN2. When the first selection signal SEL1 is the supply voltage VDD, the first multiplexer 316 may output the first selection signal SEL1 received through the first input electrode IN1. When the first selection signal SEL1 is the ground voltage GND, the first multiplexer 316 may output the second selection signal SEL2 received through the second input electrode IN2.

The oscillation unit 312 may include an oscillator 313 and a buffer 314. When the oscillator 313 receives the supply voltage VDD, the oscillator 313 may be enabled such that the oscillator 313 may generate an inner refresh clock signal IRCK. When the oscillator 313 receives the ground voltage GND, the oscillator 313 may be disabled such that the oscillator 313 may not generate the inner refresh clock signal IRCK. When the buffer 314 receives the supply voltage VDD, the buffer 314 may be enabled such that the buffer 314 may buffer the inner refresh clock signal IRCK and output the inner refresh clock signal IRCK as the refresh clock signal RCK. When the buffer 314 receives the ground voltage GND, the buffer 314 may be disabled such that the buffer 314 may not output the refresh clock signal RCK although the buffer 314 receives the inner refresh clock signal IRCK from the oscillator 313. An output electrode of the buffer 314 may be coupled to a first node N1 to which the refresh pin 204 is coupled.

The buffer unit 315 may buffer the refresh clock signal RCK received from the first node N1 and output the refresh clock signal RCK.

The second multiplexer 317 may receive the inner refresh clock signal IRCK from the oscillator 313 through a first input electrode IN1 and receive the refresh clock signal RCK from the buffer unit 315 through a second input electrode IN2. When the first selection signal SEL1 is the supply voltage VDD, the first multiplexer 316 may output the inner refresh clock signal IRCK received through the first input electrode IN1. When the first selection signal SEL1 is the ground voltage GND, the first multiplexer 316 may output the refresh clock signal RCK received through the second input electrode IN2.

The memory device 200 may selectively operate as one of the master memory device 200-1, the slave memory device 200-2 and the auto-refresh memory device 200-6 according to the voltage levels of the first selection signal SEL1 and the second selection signal SEL2 generated from the selection unit 311 a.

In some example embodiments, the selection unit 311a may include a first switch and a second switch, and each of the first switch and the second switch may include a first fuse circuit coupled to the ground voltage GND and a second fuse circuit coupled to the supply voltage VDD. The first switch and the second switch may selectively output one of the ground voltage GND and the supply voltage VDD by cutting one of the first fuse circuit and the second fuse circuit to generate the first selection signal SEL1 and the second selection signal SEL2, respectively.

For example, the first switch of the selection unit 311a included in the master memory device 200-1 may generate the first selection signal SEL1 having the supply voltage VDD by cutting the first fuse circuit, and the second switch of the selection unit 311 a included in the master memory device 200-1 may generate the second selection signal SEL2 having the supply voltage VDD by cutting the first fuse circuit. The first switch of the selection unit 311 a included in the slave memory device 200-2 may generate the first selection signal SEL1 having the ground voltage GND by cutting the second fuse circuit, and the second switch of the selection unit 311 a included in the slave memory device 200-2 may generate the second selection signal SEL2 having the ground voltage GND by cutting the second fuse circuit. The first switch of the selection unit 311 a included in the auto-refresh memory device 200-6 may generate the first selection signal SEL1 having the supply voltage VDD by cutting the first fuse circuit, and the second switch of the selection unit 311 a included in the auto-refresh memory device 200-6 may generate the second selection signal SEL2 having the ground voltage GND by cutting the second fuse circuit. In this case, one of the first fuse circuit and the second fuse circuit included in each of the first switch and the second switch of the selection unit 311 a may be cut during a manufacturing process of the memory device 200 to determine the memory device 200 as one of the master memory device 200-1, the slave memory devices 200-2 and the auto-refresh memory devices 200-6.

In other example embodiments, the selection unit 311a may include a first switch and a second switch, and the first switch and the second switch may generate the first selection signal SEL1 and the second selection signal SEL2, respectively, by selecting one of the ground voltage GND and the supply voltage VDD in response to a configuration value that is programmed from outside. Each of the first switch and the second switch of the selection unit 311 a may output the ground voltage GND when the configuration value corresponds to a first value and output the supply voltage VDD when the configuration value corresponds to a second value.

For example, the configuration value of the first switch of the selection unit 311a included in the master memory device 200-1 may be programmed as the second value such that the first switch of the selection unit 311a may generate the first selection signal SEL1 having the supply voltage VDD, and the configuration value of the second switch of the selection unit 311a included in the master memory device 200-1 may be programmed as the second value such that the second switch of the selection unit 311 a may generate the second selection signal SEL2 having the supply voltage VDD. The configuration value of the first switch of the selection unit 311 a included in the slave memory device 200-2 may be programmed as the first value such that the first switch of the selection unit 311 a may generate the first selection signal SEL1 having the ground voltage GND, and the configuration value of the second switch of the selection unit 311 a included in the slave memory device 200-2 may be programmed as the first value such that the second switch of the selection unit 311 a may generate the second selection signal SEL2 having the ground voltage GND. The configuration value of the first switch of the selection unit 311 a included in the auto-refresh memory device 200-6 may be programmed as the second value such that the first switch of the selection unit 311a may generate the first selection signal SEL1 having the supply voltage VDD, and the configuration value of the second switch of the selection unit 311 a included in the auto-refresh memory device 200-6 may be programmed as the first value such that the second switch of the selection unit 311 a may generate the second selection signal SEL2 having the ground voltage GND. Therefore, each of the memory device 200 may be determined as one of the master memory device 200-1, the slave memory device 200-2 and the auto-refresh memory device 200-6 according to the value programmed as a configuration value after the memory device 200 is manufactured.

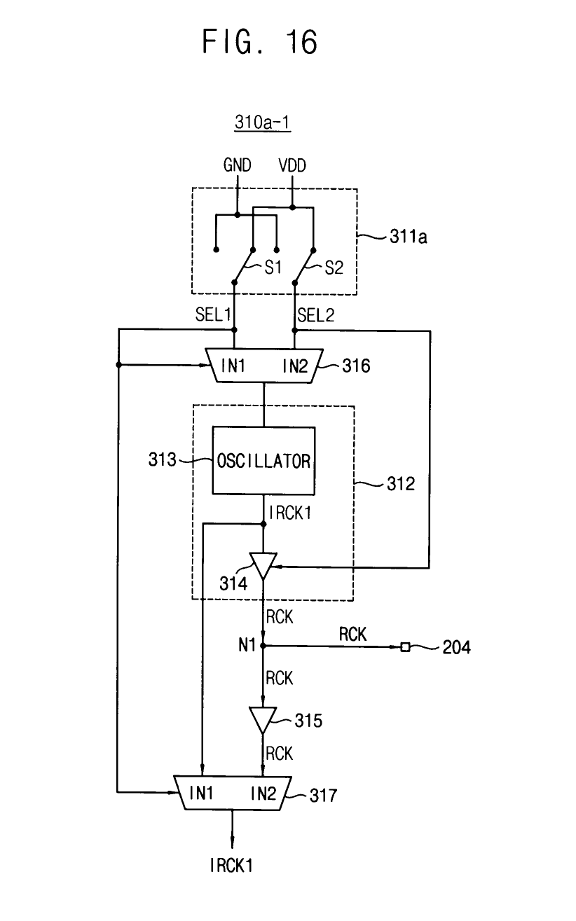

FIG. 16 is a block diagram illustrating an example of the refresh clock generator of FIG. 15 when the refresh clock generator is included in a master memory device.

Referring to FIG. 16, in the refresh clock generator 310a-1 included in the master memory device 200-1, the first switch of the selection unit 311a may generate the first selection signal SEL1 having the supply voltage VDD and the second switch of the selection unit 311a may generate the second selection signal SEL2 having the supply voltage VDD. Therefore, the first multiplexer 316 may output the supply voltage VDD and the oscillator 313 may generate the inner refresh clock signal IRCK1. The buffer 314 may buffer the inner refresh clock signal IRCK1 and output the inner refresh clock signal IRCK1 as the refresh clock signal RCK. The refresh clock signal RCK may be provided to the plurality of slave memory devices 200-2 and the plurality of auto-refresh memory devices 200-6 through the refresh pin 204. Since the first selection signal SEL1 has the supply voltage VDD, the second multiplexer 317 may output the inner refresh clock signal IRCK1 received from the oscillator 313. The inner refresh clock signal IRCK1 may be substantially the same as the refresh clock signal RCK provided to the plurality of slave memory devices 200-2 and the plurality of auto-refresh memory devices 200-6 through the refresh pin 204.

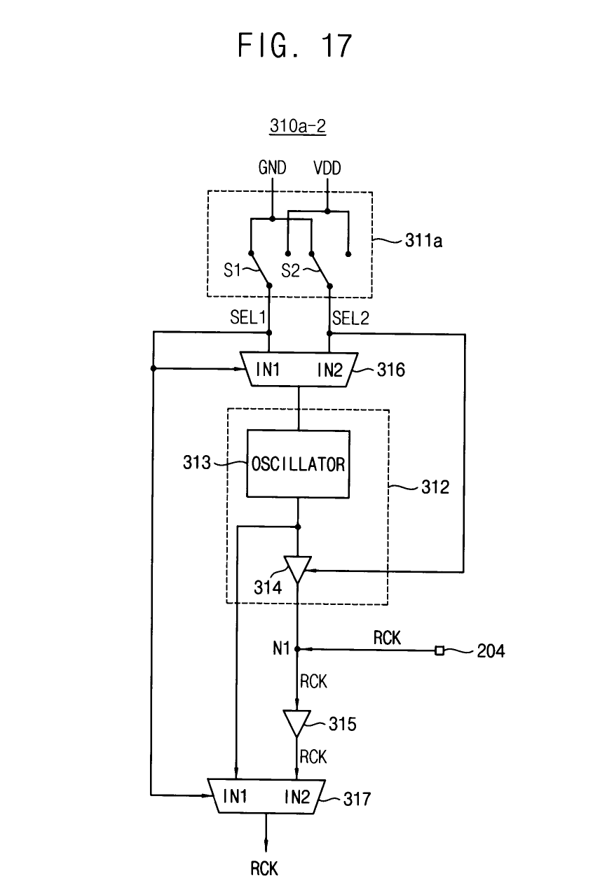

FIG. 17 is a block diagram illustrating an example of the refresh clock generator of FIG. 15 when the refresh clock generator is included in a slave memory device.

Referring to FIG. 17, in the refresh clock generator 310a-2 included in the slave memory device 200-2, the first switch of the selection unit 311 a may generate the first selection signal SEL1 having the ground voltage GND and the second switch of the selection unit 311a may generate the second selection signal SEL2 having the ground voltage GND. Therefore, the first multiplexer 316 may output the ground voltage GND, and the oscillator 313 and the buffer 314 may be disabled. Since the refresh clock signal RCK generated from the master memory device 200-1 is provided to the first node N1 through the refresh pin 204, the buffer unit 315 may provide the refresh clock signal RCK received from the first node N1 to the second multiplexer 317. Since the first selection signal SEL1 has the ground voltage GND, the second multiplexer 317 may output the refresh clock signal RCK received from the buffer unit 315.

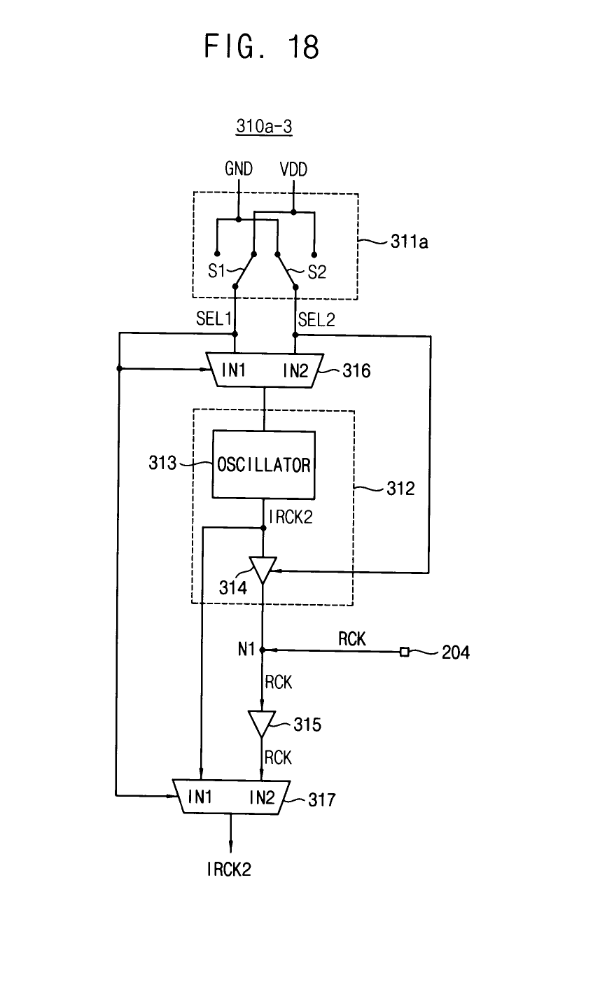

FIG. 18 is a block diagram illustrating an example of the refresh clock generator of FIG. 15 when the refresh clock generator is included in an auto-refresh memory device.

Referring to FIG. 18, in the refresh clock generator 310a-3 included in the auto-refresh memory device 200-6, the first switch of the selection unit 311 a may generate the first selection signal SEL1 having the supply voltage VDD and the second switch of the selection unit 311 a may generate the second selection signal SEL2 having the ground voltage GND. Therefore, the first multiplexer 316 may output the supply voltage VDD, and the oscillator 313 may generate the inner refresh clock signal IRCK2. The inner refresh clock signal IRCK2 may have a different period from the refresh clock signal RCK generated from the master memory device 200-1. Since the second selection signal SEL2 has the ground voltage GND, the buffer 314 may be disabled. Since the refresh clock signal RCK generated from the master memory device 200-1 is provided to the first node N1 through the refresh pin 204, the buffer unit 315 may provide the refresh clock signal RCK received from the first node N1 to the second multiplexer 317. Since the first selection signal SEL1 has the supply voltage VDD, the second multiplexer 317 may output the inner refresh clock signal IRCK2 received from the oscillator 313.

As described above, each of the plurality of auto-refresh memory devices 200-6 may generate the inner refresh clock signal IRCK2 and perform the refresh operation in synchronization with the inner refresh clock signal IRCK2 while the master memory device 200-1 and each of the plurality of slave memory devices 200-2 perform the refresh operation in synchronization with the refresh clock signal RCK generated from the master memory device 200-1. Therefore, the plurality of auto-refresh memory devices 200-6 may perform the refresh operation with a different refresh period from the master memory device 200-1 and the plurality of slave memory devices 200-2.

In addition, the master memory device 200-1, the plurality of slave memory devices 200-2 and the plurality of auto-refresh memory devices 200-6 may be implemented with the memory device 200 of FIG. 4, and the memory device 200 of FIG. 4 may selectively operate as one of the master memory device 200-1, the slave memory devices 200-2 and the auto-refresh memory devices 200-6 according to the inner configuration of the selection unit 311 a included in the refresh clock generator 310a. Therefore, a manufacturing process of the memory module 300 may be simplified.

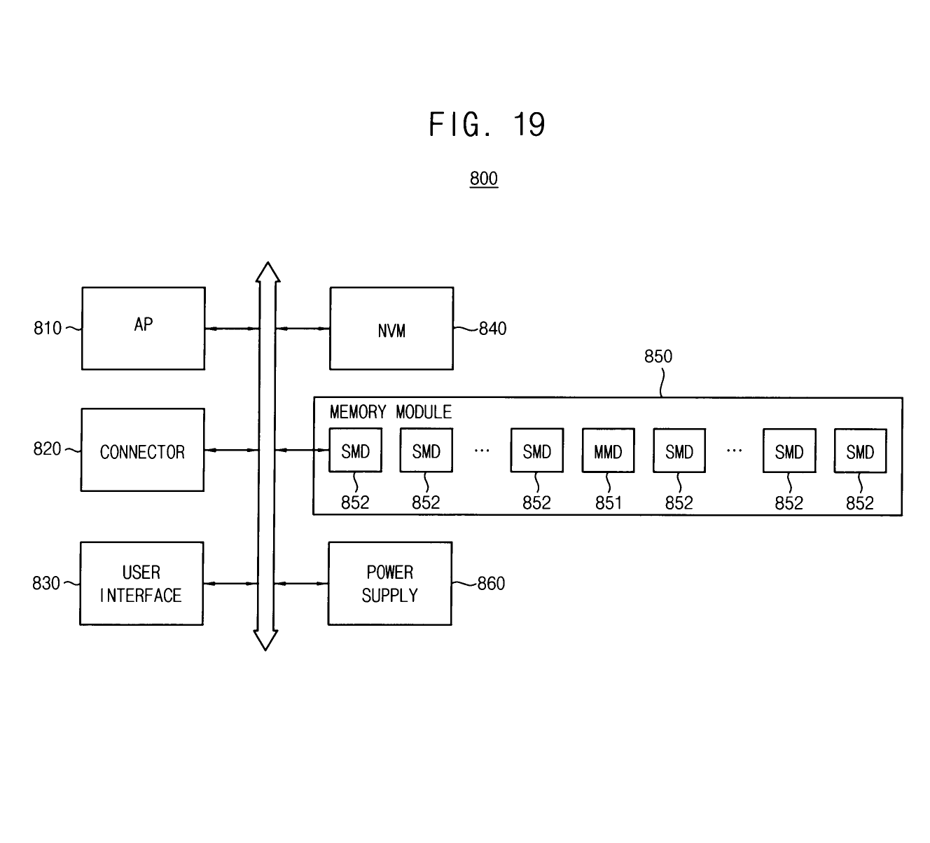

FIG. 19 is a block diagram illustrating a mobile system according to exemplary embodiments.

Referring to FIG. 19, a mobile system 800 includes an application processor 810, a connector 820, a user interface 830, a nonvolatile memory device NVM 840, a memory module 850 and a power supply 860. In some embodiments, the mobile system 800 may be a mobile phone, a smart phone, a personal digital assistant (PDA), a portable multimedia player (PMP), a digital camera, a music player, a portable game console, a navigation system, etc.

The application processor 810 may execute applications, such as a web browser, a game application, a video player, etc. In some embodiments, the application processor 810 may include a single core or multiple cores. For example, the application processor 810 may be a multi-core processor, such as a dual-core processor, a quad-core processor, a hexa-core processor, etc. The application processor 810 may include an internal or external cache memory.

The connector 820 may perform wired or wireless communication with an external device. For example, the connector 820 may perform Ethernet communication, near field communication (NFC), radio frequency identification (RFID) communication, mobile telecommunication, memory card communication, universal serial bus (USB) communication, etc. In some embodiments, connector 820 may include a baseband chipset that supports communications, such as global system for mobile communications (GSM), general packet radio service (GPRS), wideband code division multiple access (WCDMA), high speed downlink/uplink packet access (HSxPA), etc.

The memory module 820 may include one master memory device MMD 851 and a plurality of slave memory devices SMD 852. The master memory device 851 and each of the plurality of slave memory devices 852 may perform a refresh operation internally in a normal access mode as well as in a power down mode. The master memory device 851 may generate a refresh clock signal and provide the refresh clock signal to the plurality of slave memory devices 852. The master memory device 851 and each of the plurality of slave memory devices 852 may perform the refresh operation in synchronization with the refresh clock signal. The memory module 850 may be embodied similarly with the memory module 300 of FIG. 1. A structure and an operation of the memory module 300 of FIG. 1 are described above with reference to FIGS. 1 to 18. Therefore, a detail description of the memory module 850 will be omitted.

The nonvolatile memory device 840 may store a boot image for booting the mobile system 800. For example, the nonvolatile memory device 840 may be an electrically erasable programmable read-only memory (EEPROM), a flash memory, a phase change random access memory (PRAM), a resistance random access memory (RRAM), a nano floating gate memory (NFGM), a polymer random access memory (PoRAM), a magnetic random access memory (MRAM), a ferroelectric random access memory (FRAM), etc.

The user interface 830 may include at least one input device, such as a keypad, a touch screen, etc., and at least one output device, such as a speaker, a display device, etc. The power supply 860 may supply electric power to the mobile system 800.

In some embodiments, the mobile system 800 may further include an image processor, and/or a storage device, such as a memory card, a solid state drive (SSD), a hard disk drive (HDD), a CD-ROM, etc.

In some embodiments, the mobile system 800 and/or components of the mobile system 800 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

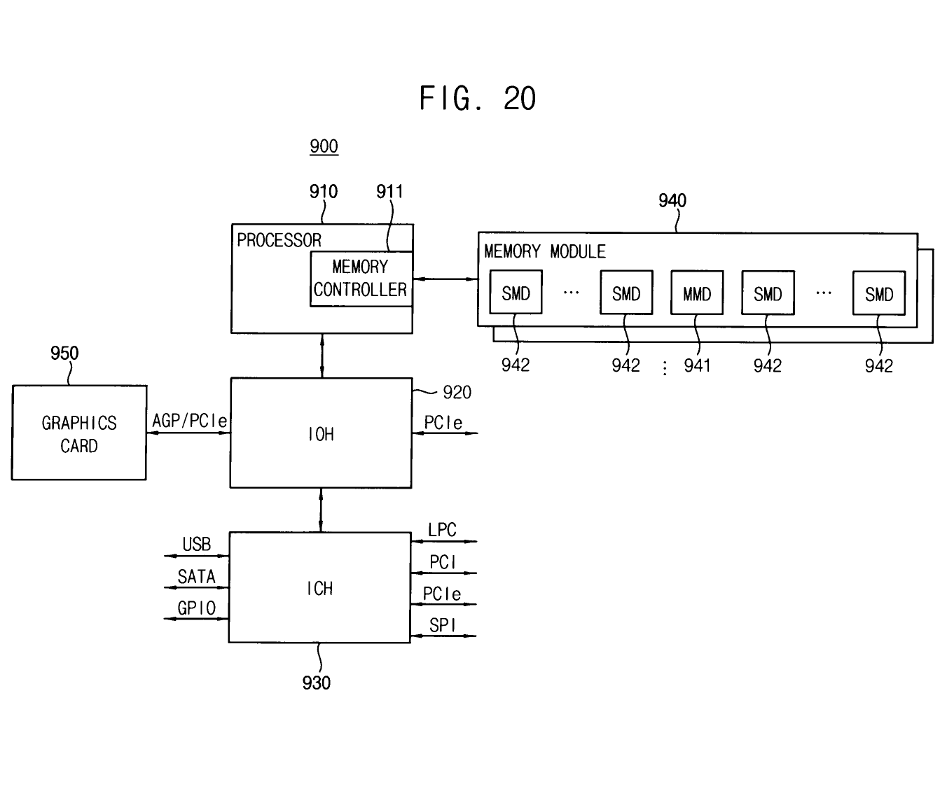

FIG. 20 is a block diagram illustrating a computing system according to exemplary embodiments.

Referring to FIG. 20, a computing system 900 includes a processor 910, an input/output hub (IOH) 920, an input/output controller hub (ICH) 930, at least one memory module 940 and a graphics card 950. In some embodiments, the computing system 900 may be a personal computer (PC), a server computer, a workstation, a laptop computer, a mobile phone, a smart phone, a personal digital assistant (PDA), a portable multimedia player (PMP), a digital camera, a digital television, a set-top box, a music player, a portable game console, a navigation system, etc.

The processor 910 may perform various computing functions, such as executing specific software for performing specific calculations or tasks. For example, the processor 910 may be a microprocessor, a central process unit (CPU), a digital signal processor, or the like. In some embodiments, the processor 910 may include a single core or multiple cores. For example, the processor 910 may be a multi-core processor, such as a dual-core processor, a quad-core processor, a hexa-core processor, etc. Although FIG. 20 illustrates the computing system 900 including one processor 910, in some embodiments, the computing system 900 may include a plurality of processors.

The processor 910 may include a memory controller 911 for controlling operations of the memory module 940. The memory controller 911 included in the processor 910 may be referred to as an integrated memory controller (IMC). A memory interface between the memory controller 911 and the memory module 940 may be implemented with a single channel including a plurality of signal lines, or may be implemented with multiple channels, to each of which at least one memory module 940 may be coupled. In some embodiments, the memory controller 911 may be located inside the input/output hub 920. The input/output hub 920 including the memory controller 911 may be referred to as memory controller hub (MCH).

The memory module 940 may include one master memory device MMD 941 and a plurality of slave memory devices SMD 942 that store data provided from the memory controller 911. The master memory device 941 and each of the plurality of slave memory devices 942 may perform a refresh operation internally in a normal access mode as well as in a power down mode. The master memory device 941 may generate a refresh clock signal and provide the refresh clock signal to the plurality of slave memory devices 942. The master memory device 941 and each of the plurality of slave memory devices 942 may perform the refresh operation in synchronization with the refresh clock signal. The memory module 940 may be embodied similarly with the memory module 300 of FIG. 1. The structure and the operation of the memory module 300 of FIG. 1 are described above with reference to FIGS. 1 to 18. Therefore, a detailed description of the memory module 940 will be omitted.

The input/output hub 920 may manage data transfer between processor 910 and devices, such as the graphics card 950. The input/output hub 920 may be coupled to the processor 910 via various interfaces. For example, the interface between the processor 910 and the input/output hub 920 may be a front side bus (FSB), a system bus, a HyperTransport, a lightning data transport (LDT), a QuickPath interconnect (QPI), a common system interface (CSI), etc. The input/output hub 920 may provide various interfaces with the devices. For example, the input/output hub 920 may provide an accelerated graphics port (AGP) interface, a peripheral component interface-express (PCIe), a communications streaming architecture (CSA) interface, etc. Although FIG. 20 illustrates the computing system 900 including one input/output hub 920, in some embodiments, the computing system 900 may include a plurality of input/output hubs.

The graphics card 950 may be coupled to the input/output hub 920 via AGP or PCIe. The graphics card 950 may control a display device for displaying an image. The graphics card 950 may include an internal processor for processing image data and an internal memory device. In some embodiments, the input/output hub 920 may include an internal graphics device along with or instead of the graphics card 950 outside the graphics card 950. The graphics device included in the input/output hub 920 may be referred to as integrated graphics. Further, the input/output hub 920 including the internal memory controller and the internal graphics device may be referred to as a graphics and memory controller hub (GMCH).

The input/output controller hub 930 may perform data buffering and interface arbitration to efficiently operate various system interfaces. The input/output controller hub 930 may be coupled to the input/output hub 920 via an internal bus, such as a direct media interface (DMI), a hub interface, an enterprise Southbridge interface (ESI), PCIe, etc.

The input/output controller hub 930 may provide various interfaces with peripheral devices. For example, the input/output controller hub 930 may provide a universal serial bus (USB) port, a serial advanced technology attachment (SATA) port, a general purpose input/output (GPIO), a low pin count (LPC) bus, a serial peripheral interface (SPI), PCI, PCIe, etc.

In some embodiments, the processor 910, the input/output hub 920 and the input/output controller hub 930 may be implemented as separate chipsets or separate integrated circuits. In other embodiments, at least two of the processor 910, the input/output hub 920 and the input/output controller hub 930 may be implemented in a single chipset.

The foregoing is illustrative of the present disclosure and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. Therefore, it is to be understood that the foregoing is illustrative of various example embodiments and is not to be construed as limited to the specific example embodiments disclosed. Accordingly, modifications of the disclosed example embodiments and other example embodiments are intended to be included within the scope of the appended claims.

What is claimed is:

1. A memory module, comprising:
a master memory device configured to generate a refresh clock signal, and to perform a refresh operation in synchronization with the refresh clock signal; and
a plurality of slave memory devices configured to receive the refresh clock signal, and to perform a refresh operation in synchronization with the refresh clock signal.

2. The memory module of claim 1, wherein each of the master memory device and the slave memory devices comprises a refresh pin and is configured to transmit and/or receive the refresh clock signal through the refresh pin.

3. The memory module of claim 2, wherein the master memory device is connected to each of the plurality of slave memory devices to directly provide the refresh clock signal to each of the plurality of slave memory devices through a corresponding refresh pin.

4. The memory module of claim 2, wherein the master memory device is connected to an adjacent slave memory device to provide the refresh clock signal to the adjacent slave memory device through the refresh pin of the adjacent memory device, and each of the remaining plurality of slave memory devices receives the refresh clock signal through a corresponding first refresh pin and provides the refresh clock signal to a corresponding adjacent slave memory device through a corresponding second refresh pin.

5. The memory module of claim 2, wherein each of the master memory device and the slave memory devices comprises:
a selection circuit configured to selectively output one of a first voltage and a second voltage;
an oscillation circuit configured to be disabled when receiving the first voltage from the selection circuit, and configured to generate the refresh clock signal and provide the refresh clock signal to a first node to which the refresh pin is coupled when receiving the second voltage from the selection circuit; and
a buffer configured to buffer the refresh clock signal received from the first node and output the refresh clock signal,
wherein the selection circuit in the master memory device is configured to output the second voltage and the selection circuit in each of the slave memory devices is configured to output the first voltage.

6. The memory module of claim 5, wherein the selection circuit is configured to selectively output one of the first voltage and the second voltage according to a fuse in the selection circuit.

7. The memory module of claim 5, wherein the selection circuit is configured to selectively output one of the first voltage and the second voltage according to a programmed configuration value.

8. The memory module of claim 1, further comprising:
a plurality of auto-refresh memory devices configured to perform refresh operation in response to a refresh command received from a memory controller.

9. The memory module of claim 8, wherein each of the plurality of auto-refresh memory devices is configured to generate an inner refresh clock signal, and to perform the refresh operation in synchronization with the inner refresh clock signal when receiving the refresh command from the memory controller.

10. A memory system, comprising:
a memory module; and
a memory controller configured to control the memory module,
wherein the memory module comprises,
a master memory device configured to generate a refresh clock signal, and to perform a refresh operation in synchronization with the refresh clock signal, and
a slave memory device configured to receive the refresh clock signal, and to perform a refresh operation in synchronization with the refresh clock signal.

11. The memory system of claim 10, wherein each of the master memory device and the slave memory device is configured to accept an active command for a first row address from the memory controller while performing a refresh operation on the first row address and to perform the active command for the row address after finishing the refresh operation on the row address.

12. The memory system of claim 11, wherein each of the master memory device and the slave memory device is configured to accept a read command from the memory controller after accepting the active command and to perform the read command after a row address-to-column address delay (tRCD) from a time at which the active command is performed and provide a data strobe signal (DQS) and transmit read data to the memory controller after a column address strobe (CAS) latency (tCL) from a time at which the read command is performed.

13. The memory system of claim 12, wherein, the memory controller is configured to sample the read data in synchronization with the data strobe signal (DQS) provided from the master memory device or one of the slave memory device.

14. The memory system of claim 11, wherein each of the master memory device the slave memory device are configured to accept a write command from the memory controller after accepting the active command and to perform the write command after a row address-to-column address delay (tRCD) from a time at which the active command is performed and to continuously toggle a data strobe signal (DQS) from a time at which the toggling of the data strobe signal (DQS) provided from the memory controller stops until the performance of the write command finishes.

15. The memory system of claim 14, wherein, the memory controller is configured to determine that a write operation on the master memory device or the slave memory device finishes at the time when a toggling of the data strobe signal (DQS) provided from the master memory device or the slave memory device stops.

16. The memory system of claim 10, wherein the memory controller is configured to send a read command, a write command and an address signal to each of the master memory device and the slave memory device, and the master memory device is configured to send the refresh clock signal to at least one of the slave memory devices.

17. A memory module comprising:
a master memory device configured to generate a refresh clock signal and to perform a refresh operation in synchronization with the refresh clock signal; and
a slave memory device configured to receive the refresh clock signal and to perform a refresh operation in synchronization with the refresh clock signal.

18. The memory module of claim 17, wherein each of the master memory device and the slave memory device comprises a refresh pin configured to transmit and/or receive the refresh clock signal.

19. The memory module of claim 18, wherein each of the master memory device and the slave memory device further comprises: a first node coupled to the refresh pin;
a selection circuit configured to output one of a first voltage and a second voltage;
an oscillation circuit configured to be disabled when receiving the first voltage from the selection circuit, to generate the refresh clock signal when receiving the second voltage from the selection circuit, and to provide the refresh clock signal to the first node; and
a buffer configured to store the refresh clock signal received from the first node and output the refresh clock signal,
wherein the selection circuit in the master memory device is configured to output the second voltage and the selection circuit in the slave memory device is configured to output the first voltage.

20. The memory module of claim 17, further comprising:
an auto-refresh memory device configured to perform a refresh operation in response to a refresh command from a memory controller,
wherein the auto-refresh memory device is configured to generate an inner refresh clock signal and to perform the refresh operation in synchronization with the inner refresh clock signal when receiving the refresh command from the memory controller.
